(19) United States
(12) Patent Application Publication
(10) Pub. No.: US 2024/0222641 A1
(43) Pub. Date: Jul. 4, 2024

(54) METHOD FOR OPTIMIZING MATERIAL PROPERTIES OF COMPONENTS OF A BATTERY, MANUFACTURING A FIBER NETWORK, AN ELECTRODE AND A BATTERY

(71) Applicant: MAX-PLANCK-GESELLSCHAFT ZUR FÖRDERUNG DER WISSENSCHAFTEN E.V., München (DE)

(72) Inventors: Timotheus JAHNKE, Stuttgart (DE); Yuanzhen WANG, Böblingen (DE); Erik FARLEY, Sindelfingen (DE); Joachim SPATZ, Stuttgart (DE)

(21) Appl. No.: 18/289,132

(22) PCT Filed: May 19, 2021
(86) PCT No.: PCT/EP2021/063333

§ 371 Date: Nov. 1, 2023

(51) Int. Cl. H01M 4/66; G06F 30/27; H01M 4/02; H01M 4/505; H01M 4/525; H01M 4/62; H01M 10/0525

(52) U.S. Cl. CPC H01M 4/663; G06F 30/27; H01M 4/505; H01M 4/525; H01M 4/623; H01M 4/625; H01M 10/0525; H01M 2004/021

(57) ABSTRACT

The present invention relates to a method for optimizing material properties of components of a battery comprising the following steps: Inputting material parameter data, with said material parameter data relating to properties of constituents of the components of the battery; simulating one or more components and/or constituents of components of the battery using a simulation model which takes the material parameter data as input to generate simulation result data as output, with the simulation result data comprising at least one of the following data: data on microscopic geometric features of the component, data on a conductivity of the component, data on a current collector, data on a binder phase, data on a diffusivity of the electrolyte and data on a charging and discharging potential of the component; training an AI model with the material parameter data as input and the simulation result data as output; evaluating a final accuracy of the AI model with respect to the simulation model using extended material parameter data; using the AI model to output material properties of the constituents of the components of the battery. The invention further relates to a method for manufacturing a fiber network, to an electrode and to a battery.

The invention relates to a method for optimizing material properties of components of a battery. The invention further relates to a method for manufacturing a fiber network, to an electrode and to a battery.

In light of the climate change the use of multivalent-ion batteries and in particular of lithium-ion batteries in the electromobility space has become more and more popular. However, the optimization and the design of electrodes for such batteries comes with a large number of experiments, which need to be conducted, leading to limited progress. Furthermore, the large number of different components, additives and electrolyte systems makes it increasingly difficult to determine optimization parameters, and, even if such trends are shown, changes might have a large influence on a different component of the electrochemical cell.

In order to limit the experimental time and to be able to test a larger number of different experimental setups, virtual material design might be feasible. Virtual design of components is already an established field in the design of components for cars which experience a large mechanical load on the basis of simulated stress tests or the design of an airplane's wings on the basis of airflow simulations. However, for such complicated systems like electrodes, which involve highly complex operations and physical correlations between the properties of the constituents of the electrode, e.g. liquid diffusivity in the electrolyte, electronic properties of the solid phase or electrochemical intercalation properties of the active material, virtual design of all components is due to the large number of different parameters highly inefficient. Hereby, the calculation of the intercalation process requires large computing times due to the large surface and complicated electrode structure. Consequently, the simulation of multiple material parameter configurations of the electrode requires a large amount of time. Since the intercalation process and electrode structure cannot be simplified without losing essential information about the process, the number of required simulations should be reduced.

It is therefore a main object of the invention to provide a method for optimizing material properties of components of a battery which reduces the number of required simulations.

This objective is satisfied by a method in accordance with claim 1.

Description of the invention and preferred embodiments:

According to a first aspect of the invention a method for optimizing material properties of components of a battery is provided, comprising the following steps:
(1) inputting material parameter data, with set material parameter data relating to properties of constituents of the components of the battery;
(2) simulating one or more components and/or constituents of components of the battery using a microstructure based simulation model which takes the material parameters as input to generate simulation result data as output, with the simulation result data comprising at least one of the following data: data on microscopic geometric features of the component, data on the conductivity of the component, data on a current collector, data on a binder phase, data on a diffusivity of the component and data on a charging and discharging potential of the component;
(3) training an AI model with the material parameter data as input and the simulation result data as output;
(4) evaluating a final accuracy of the AI model with respect to the simulation model using extended material parameter data;
(5) outputting material properties of the constituents of the components of the battery.

In this connection it should be noted that the respective data also comprises the structure of the respective component and/or constituent.

The method is hence based on the idea of simulating one or more components of a battery, such as an electrode and in particular a microstructure thereof. In order to simulate this component, certain boundary conditions exist at least some of which are input into the simulation program. This data comprises material parameter data as input data for the method. The material parameter data relates to material properties of constituents of the components of the battery and in particular of the electrode, and the simulation of the one or more components outputs simulation result data corresponding to geometric features or physical properties of the component.

By way of example, the microstructure can comprise a fiber network forming material of an electrode of the battery. Such a network of fibers typically comprises a plurality of metal fibers of a metal or metal alloy composition that are fixed to one another and wherein the metal fibers have a length of 1.0 mm or more, a width of 100 μm or less and a thickness of 50 μm or less. The fiber may optionally have a circular or oval cross section area with a diameter of less than 100 μm, preferably less than 10 μm. In case of an oval cross section, the mentioned diameter is the average diameter. For example, the oval cross section has the shape of an ellipse.

Other parameters of the fiber network may comprise a fiber material, e.g. the metal or metal alloy that makes up the composition of the fiber, e.g. Cu96Si4, Al99Si1, Cu, Al, Cu88Si12, Cu97Si3, Sn, Mo, Au, Ag, Pd, PI a fiber curvature, a fiber cross section geometry, a fiber diameter, a fiber distribution orientation, a fiber conductivity or combinations of the foregoing. In order to obtain a common network, the fiber curvature is isotropic with a 5% deviation of the initial angle after a length of 5 μm, the fiber cross section geometry is elliptical with a ratio between larger and smaller radius of 0.8, the fiber diameter ranges between 10 and 100 μm, preferred is a diameter of 35 μm and even more preferred a diameter of 15 μm or smaller, the fiber distribution might be completely isotropic, or selected from an anisotropic tensor, which indicates the mean orientation of all fiber (i.e. anisotropic tensor=(0 0 1), which leads to perfect alignment in z-direction), as fiber conductivity (since it is a material inherent parameter) a conductivity of Copper (6.5*10\hat{ }7 S/m) can be selected, but is not necessarily given.

Once the simulation of one or more components of the battery is complete, the simulation result data are output. The simulation result data comprises at least of one of the following data: data on microscopic geometric features of the component, data on a conductivity of the component, data on a current collector, data on a binder phase, data on a diffusivity of the component and data on a charging and discharging potential and behaviour of the component, i.e. parameters that such a component of the battery may have if assembled from the real constituents which make up a respective component and its performance, such as charging-discharging potential at different current rates can be obtained.

By way of example, the simulation of the microstructure can be carried out by commercially available software, such as the program GeoDict available from Math2Market. In this connection it should be noted that other programs that are able to simulate a microstructure according to given parameters as those discussed herein are suitable for the purpose of this invention.

This simulated structure can and if possible should be correlated with an experimental structure. For example, a correlating microstructure of a real object can be obtained for example by using a Micro-CT scan and reconstruct the respective object.

It should be noted in this connection that the present method is not limited solely to the use and reconstruction by Micro-CT, but also comprises free microstructural simulations, in which a real structure is only resembled and can be subsequently simulated without the need for checking with a real object. The comparison with a real object is preferably carried out on testing the simulation in order to evaluate whether the simulation results represent a real-world object.

An AI model is then trained with the material parameter data as input and the corresponding simulation result data as output/labels. The AI model attempts to predict the simulation result data of the corresponding material parameter data and compares its prediction with the actual simulation result data to generate an error which is used to determine whether the AI model is well-trained.

In a next step the final accuracy of the AI model is evaluated with respect to the simulation model by using extended material parameter data which is different from the material parameter data.

Thereby, the performance of the AI model regarding new material parameter data, i.e. new material parameter configurations of the component, can be tested. When the final accuracy of the AI model reaches a predefined value (might be absolute or relative), the AI model is considered to be an accurate representation of the simulation model and therefore can be used independently. In a final step the independent AI model is then used to output material properties of the constituents of the components of the battery and in particular of the electrode.

With the AI model it is possible to replace the simulation model in the course of the parameter optimization. The simulation model runs a number of simulations until the final accuracy of the AI model reaches a predefined value and can then be replaced by the AI model. Testing of new material parameter configurations may subsequently be performed by the AI model and not the simulation model. Hence, when the AI model reaches a certain accuracy, time-consuming simulations run by the simulation model can dispensed with. Thereby a simulation time and/or computing power can ultimately be reduced.

According to one embodiment of the invention the battery is an electrochemical energy storage device and preferably a multivalent-ion or monovalent-ion battery. It is preferable if the battery is a calcium-ion or aluminium-ion battery and even more preferably a lithium-ion battery. It is to be understood, that the battery may also be any other kind of battery. Thereby the method according to the invention can beneficially be used to simulate one or more components of a variety of types of batteries.

According to one embodiment of the invention the components of the battery are selected from a group of members consisting of one or more electrodes, a current collector, a positive electrode, a negative electrode, a separator, an electrolyte (solid or liquid), combinations of the foregoing or any other kind of battery component. Thereby the method can simulate a plethora of types of components of batteries and also of half cells. In this connection it should be noted that a half cell is half of an electrolytic or voltaic cell, e.g. battery, in which the reaction is tested against a metallic counter electrode, e.g. metallic lithium. Half cells are used to investigate single components of a battery in order to investigate their specific characteristics.

According to one embodiment of the invention the constituents of the components of the battery are selected from a group of members consisting of a fiber network, an active material (AM), a binder, a conductive additive and an electrolyte and combinations of the foregoing or any other kind of constituents of an electrode. Such constituents make up the essential components of batteries and half cells.

It is preferred if the fiber network comprises a plurality of fibers and if a material of the plurality of fibers comprises metal or carbon. In this way a conductive network can be made available through which ions diffuse bringing about the characteristics of a battery and/or its components and/or its constituents.

It is also preferred if the active material is selected from a group of members consisting of graphite, silicon, silicon/carbon composite, silicon-dioxide/carbon composite, tin, tin-oxide or any of the composites, lithium metal of a lithium metal composite and any other anode active material or Lithium-Nickel-Manganese-Cobalt-Oxide (NMC) in any kind and stoichiometry, e.g. 811, 910, 190, 091, 111, 532, 622, Lithium Iron, e.g. Manganese, Nickel, Cobalt, phosphate (LF(M,N,C)P), Spinel type manganese oxide (Mn₂O₄) and any other cathode active material. Such active materials are successfully used in batteries.

It is further preferable if the binder is selected from a group of members consisting of polyvinylidene fluoride or styrene-butadiene copolymer, carboxymethylcellulose, polyvinylidene fluoride hexafluoropropylene, alginates and polyvinylalcohole or any other kind of polymeric binder. These are binders as commonly used for batteries, also further binders can be used in the present invention.

Moreover, it is preferable if the conductive additive is selected from a group of members consisting of carbon black, Super P in any kind of size (e.g. C40, C45, C60), Carbon Nanotubes, graphene and metal nanowires (e.g. silver, copper) or any other kind of conductive additive. Such conductive additives are successfully used in batteries.

It is preferred if the material parameter data comprises data on the fiber network properties and/or data on the AM properties and/or data on the electrolyte properties and/or data on the structure of the material and/or any other material-related property of the constituents of the components of the battery. The more data that is input the more effective and reliable the simulation of the component of the battery is.

The material parameter data may comprise data regarding one or a plurality of simulation runs and therefore may comprise a vector or a matrix representing multidimensional data. Hereby, the matrix might be composed, but is not limited to a tensor, e.g. (1 0 0; 0 1 0, 0 0 1) for the conductivity is a metal as an isotropic conductivity tensor as a simple example. If this is combined with further parameters, the size of the matrix is increasing correspondingly. For example, if the material parameter data comprises a vector, at least one element of the vector may comprise data on a fiber network property and/or AM property and/or electrolyte property.

If the material parameter data comprises a matrix, at least one column of the matrix may indicate a fiber network property and/or AM property and/or electrolyte property, whereas a row of the matrix may indicate an index number of a simulation run such as charging rate between 0.1 to 1 C in 0.1 C steps, or vice versa. For example, the matrix comprises the discharge capacity at a discharging rate of 0.5 C over a number of different geometries N1 and a number of fiber densities N2, then the resulting matrix has a dimension of 2, with a length of the rows=N1 and the length of the columns=N2. This matrix however is not confined to 2 dimensions, but can be simply extended into further dimensions if different parameters like the charging rate are varied. It is to be understood, that the material parameter data may be structured in any other kind of possible shape. As multiple simulations are run by the simulation model in order to generate an adequate amount of data, it is preferred if the material parameter data comprises a matrix, wherein it is preferred if each row or column of the matrix comprises all relevant data related to a corresponding simulation run.

It is particularly preferred if the data on the fiber network properties is selected from a group of members consisting of a fiber density, a fiber length, a fiber curvature, a fiber cross section geometry, a fiber diameter, a fiber distribution orientation, a fiber conductivity, combinations of the foregoing or any other fiber-related property.

In order to obtain a common network, the fiber curvature is isotropic with a 5% deviation of the initial angle after a length of 5 μm, the fiber cross section geometry is elliptical with a ratio between larger and smaller radius of 0.8, the fiber diameter ranges between 10 and 100 μm, preferred is a diameter of 35 μm and even more preferred a diameter of 15 μm or smaller, the fiber distribution might be completely isotropic, or selected from an anisotropic tensor, which indicates the mean orientation of all fiber (i.e. anisotropic tensor=(0 0 1), which leads to perfect alignment in z-direction), as fiber conductivity (since it is a material inherent parameter) a conductivity of Copper (6.5*10\hat{ }7 S/m) can be selected, but is not necessarily given. In the non-ideal case, the fibers volume is occupying to much simulation space and the fibers cannot be distributed accordingly. Therefore, a set of parameters with a low fiber density and a high fiber thickness is non-ideal.

Furthermore, it is preferable if the data on the AM properties is selected from a group of members consisting of an AM fraction, an AM particle size, an AM particle shape, an AM conductivity, an AM diffusivity, an AM equilibrium open circuit potential, an AM reaction rate, combinations of the foregoing or any other AM-related property.

It is preferred if the particle size of graphite is a particle size distribution from 5 to 40 μm with a maximum in the histogram at 13 μm-15 μm and if the general shape of graphite is polyhedral with an isotropic electrical conductivity of 100 S/m, Lithium-ion diffusivity of 2e⁻¹³ m²/s and a density of 2000 g/cm³. However, to better represent the reality of the material parameters, an anisotropic behavior of conductivity and diffusivity can be added for the graphite example. The open circuit potential is a function of the Lithium capacity of graphite with a maximum at 26390 mol/m³ and is also dependent on the hysteresis of the charging-discharging curve (Lithium inter-/deintercalation). The reaction rate is summarized as the Butler-Volmer rate of 8.5e⁻⁷ Am^{2.5}/mol^{1.5}. Also transitions between different materials must be included by adding e.g., contact resistances.

It is further preferable if the data on the electrolyte properties is selected from a group of members consisting of an initial concentration, a transference number, an electrolyte diffusivity, a combination of the foregoing or any other electrolyte-related property.

The preferred conductivity of the electrolyte is 1.1 S/m, the preferred equilibrium lithium concentration is 1200 mol/m³, the preferred ionic diffusion constant is 3e⁻¹⁰ m²/s and the preferred lithium transfer number is 0.399.

According to one embodiment of the invention the simulation model is based on a microstructure simulation of the constituents of the components of the battery. Microscopic simulation indicates that the simulated structure contains all the morphological information of each component, e.g. the graphite particle size distribution, grain orientation and distribution, fiber networks orientation, density, pore size distribution, etc. Thus no geometrical feature is simplified. Unlike macroscopic simulation, microscopic simulation neither homogenize the structure within a so-called representative volume element, nor homogenize the physical characteristic within composite. Thus, a microscopic simulation contains the detailed information of each component and the detailed simulation result (e.g. potential field; current density) within the composite.

Additionally, the simulation model is based on physical principles and mathematical approximations. The underlying physical principles may comprise Ohm's Law governing the electronic movement, Fick's Law governing the diffusion process, Nernst-Plank equation governing the ionic movement under a certain concentration gradient and electric field and Butler-Volmer equation governing the electrochemical reactions, whereas the underlying mathematical approximations comprise a discretization of the partial differential equations during solving for the microscopic simulation.

The model is based on the Butler-Volmer equation (eq.) as described by Latz et al. (Latz, A. & Zausch, J. Thermodynamic derivation of a Butler-Volmer model for intercalation in Li-ion batteries. Electrochimica Acta 110, 358-362 (2013).) It is assumed that the transition of the Li-ion, from the electrolyte to the AM, is a change in the chemical activity at the interface between AM and electrolyte, without the occurrence of a chemical reaction. Hence, this model doesn't include solvation and dissolvation of the Lithium-Ions in the electrolyte as energetic contribution, however; it calculates the ion concentration and its depletion upon intercalation in the electrolyte.

Moreover, it is preferable if the microstructure simulation is based on a Finite Element Model (FEM) and even more preferable if the microstructure simulation is based on a Finite Volume Model (FVM) of the component structure.

The FEM is a systematic numerical method for solving problems of engineering and mathematical physics, more specifically partial differential equations (PDEs). The method gives solutions to boundary value problems for PDEs. Thus, to solve the problem, FEM subdivides a large system into smaller, simpler parts called finite elements, use variational method from the calculus of variations to estimate solution by minimizing a related error function within this element, and then compiled it into a large system of equations that described the entire problem.

FVM, on the other hand, is a numerical technique to evaluate a volume as a discrete place over a meshed geometry (e.g. a vortex-based geometry), and directly transfer the PDEs into a set of linear algebraic equations within this volume. Thus, although FEM permits higher accurate approximation locally with high order polynomials, it requires large amount of computing power and consumes time. In contrast, Finite Volume Method is the nature choice for solving conservation equations with lower order, e.g. Fick's Law, and thus more suitable for describing the flow rate or particle movement, i.e. the movement of electrons in the component of the battery and the movement of ions in the electrolyte. Moreover, the FVM is based on voxel structures. Thus, the structure (structure surface) does not need to be meshed like in a FEM model, which would consume large computation power when studying microscopic properties. Furthermore, FEM's accuracy is highly depended on the mesh quality, for microscopic structures, it's hard to reach a high mesh quality, which impacts the simulation result.

According to one embodiment of the invention the structure of the component of the battery is obtained on the basis of statistical parameters extracted from Micro-CT scans of the fiber network and/or Micro-CT scans and/or FIB-SEM scans of the active material particles.

Hereby the FIB SEM is used to obtain a model structure of the graphite particles and by mathematical means (bubble Point, Euclidian circle) the statistical size distribution and their geometry can be obtained. According to these statistical parameters, a finite volume model can then be reconstructed, which correlates with the experimental size and geometry of said particles. As such, the obtained model is a digital twin of the particles and structure.

Using common software, e.g. CT-AN from Bunker, GeoDict from Math2Market or any other comparable software, the Micro-CT scan of the microstructure may be reconstructed into a volume structure. On the basis of the volume structure or a multitude of them properties of the constituent of the components of the battery may be obtained by mathematical evaluations, e.g. Euclidic Distance. The obtained structural values may be used and correlated with material parameter data for the simulation model.

It is particularly preferred if the microstructure simulation is correlated with an experimental structure. The experimental structure of the electrode may be obtained by the Micro-CT scan of the fiber network. By comparing key parameters, i.e. material parameter data and simulation result data, of the experimental structure and the microstructure simulation, a correlation between microstructure simulation and experimental structure may be established. For instance, parameters of a copper-silicon-network (CuSi₄-network) with a fiber diameter of 35 μm, a volume fraction of 5 v % which is occupied by fibers in the network and a mean distance between the fibers of 195 μm, may be directly correlated with a corresponding simulated fiber network based on these parameters. In another example the obtained conductivity of the electrode can be correlated with 4-point conductivity measurements on an experimental electrode. Among others, similar experimental techniques can be applied for the respective properties, i.e. EIS/GITT or PGSE-NMR for diffusivity, charging-discharging tests on half or full cells for the charging/discharging profiles, contact angle measurements to obtain the wetting behavior.

In detail, a material parameter like the conductivity is given as scalar values (e.g. 6.5*10\hat{ }7 S/m for copper). However, the conductivity of the electrode does not solely depend of this single parameter, but the assembly of the single components in the electrode, such as AM, fibers, Carbon-Black phase, etc. Thus, using e.g. four-point-conductivity measurements on an experimental network, we are able to determine the conductivity of the electrode. This measured conductivity can be correlated with the conductivity of the simulated structure, taking all components and assembly into account. Both values (simulation and experimentally obtained conductivity) are equal, within a certain range of error.

According to one embodiment of the invention the simulation model comprises a simulation of the fiber network. In particular, a Multiphysics simulation is used to simulate the fiber network's structure. More specifically, the fibers of the fiber network structure are defined by their inherent geometry, e.g. round, elliptical, semielliptical, square or any other geometric structure, their length, their in-plane torsion, and out-of-plane bendability. In particular, the fiber network is formed by the fibers' orientation, e.g. isotropic or anisotropic, their overlap, e.g. forced, partly or without overlap, and the fiber distribution, e.g. homogeneous or heterogeneous. Respective material properties such as conductivity, Youngs Modulus, contact resistance or any other material property of any material or element, e.g. copper, CuSi₄, or carbon can be assigned to the fibers of the simulated fiber network and resulting physical properties can then be simulated based on physical principles, e.g. Ohm's Law (U=R*I) or Fick's Law (J=dc/dt), and mathematical approximations.

Specifically, a fiber network structure is modelled, to investigate the electrical conductivity for instance. An electrical field will be applied on the boundary, the governing equations (Ohm's law) are then discrete into linear form in very vortex, an error function which describes the calculation error is also applied, the simulation solver will solve the governing functions and error functions iteratively within every vortex and try to minimize the error function. When the error function value is below a predefined value, calculation finished and thus we are able to get the potential and current flow in every vortex in the structure. Similarly, other conservation governing equations (for instance, Fick's law) are also able to be applied on the structure and carry out the same calculation process.

According to one embodiment of the invention the simulation model comprises a simulation of the active material and/or the binder and/or the conductive additives. The simulation of the active material is particularly based on statistical parameters, e.g. size distribution, shape or any other statistical parameter of experimental AM particles and preferably of experimental graphite particles. The particle size and shape of the experimental graphite particles may be obtained based on prior FIB-SEM scans. Simulated AM particles may comprise any shape, volume distribution overlap with surrounding material and inherent material parameters. However, it is preferred if the particles have a polyhedral shape, are isotropically distributed in the volume, have no overlap with surrounding material and possess the inherent material parameters, i.e. solid diffusivity of graphite concerning conductivity, ion diffusivity and maximum lithium concentration.

It is preferred if the simulation of the active material comprises filling the binder and/or the conductive additive into the active material. It is more preferred if the binder and/or the conductive additive is filled into the active material as flexible mass, which preferably complies with the following boundary condition:
The binder phase is simulated as flexible mass, i.e. voxels may be freely distributed,
the binder phase is required to connect two graphite particles and therefore no free-standing binder mass is allowed and
the binder phase structure is determined a wetting angle between active material and binder phase.

The binder phase is simulated as a concave meniscus with a contact angle between its phase and the respective material. It creates the binder phase at the closest points at the surfaces of the structure materials (a circle with the smallest radius). The termination criterions are the volume fraction, weight percentage and overall grammage. However, to resemble more the reality an anisotropic factor for the binder generation can be added.

It is particularly preferred if the simulation of the fiber network and the simulation of the active material and/or the binder and/or the conductive additive are overlapped. This allows to run simulations of the fiber network and simulations of the active material in parallel and therefore to minimize the required processing power. When overlapping both simulated structures the overlap volume fraction may be assigned as fiber material. Alternatively, the simulated fiber network may be directly filled with active material and the binder phase may be simulated into the fiber network structure.

In this case, the initial fiber structure is already loaded in the simulation volume, where the grains will be created. There are two options possible:
1) Prohibiting the overlap of the generated grains with the initial structure. The grains are then placed around the structure without overlapping with it.
2) Removing the overlap. This option generates the grains in the first step in the whole volume, with the boundary conditions set to the generation, as if the initial structure is not present. In the second step, the overlapping grains are shifted and rotated in a manner, that the overlap with the initial structure is removed. While shifting and rotating the grains, the grains can overlap with themselves. This option can be used to simulate inhomogeneities around the initial structure.
However, both generation options need more calculation power due to more iteration steps.

According to one embodiment of the invention the data on the microscopic geometric features of the component comprises a mean pore size and/or a pore size distribution and/or a contact area between the active material and the electrolyte.

According to one embodiment of the invention the data on the conductivity of the component comprises a conductivity tensor, e.g. a 3D tensor for conductivity along the X, Y, Z plane. The conductivity σ might not be isotropic (due to inherent properties as present in graphite and/or orientation in the structure (as present in a carded fiber network). As such, the resulting conductivity is given as shown below:

$$\begin{matrix}xx & yx & zx \\ xy & yy & zy \\ xz & yz & zz\end{matrix} = σ$$

According to one embodiment of the invention the data on the current collector comprises structural features, e.g. fiber density, geometry, shape, conductivity, orientation, and their physical features, e.g. conductivity, mass density.

For example, the used structure was a 1000×1000×1000 voxel structure with a variable resolution of 1 μm and a variable fiber fraction of 2 v % and a number of 100 seeds, wherein the fiber network was isotropic with a forced overlap. The fiber geometry was elliptical or curved, the fiber length was set to 5 mm and the variable fiber diameter width followed a gaussian distribution with a deviation of d/5 and a cut off of d/10. The fiber diameter thickness was set to 0.8*width, while the fiber curl was isotropic and the curl factor was 0.05 in 5 μm segments.

According to one embodiment of the invention the data on the binder phase comprises a conductivity and/or an ion-diffusivity and/or a mass.

More specifically, the data on the binder phase may comprise a Binder SVP, a contact angle, a homogeneity and an electrical conductivity. For example the binder SVP is 10%, the contact angle is 10 DEG, the binder is homogeneously distributed, the ionic diffusivity is 1.5e⁻¹⁰ m²/s and the electrical conductivity is set to 10 S/m.

According to one embodiment of the invention the data on the diffusivity of the electrolyte comprises a self-diffusion coefficient of the electrolyte and/or wetting angles and in particular wetting angles with the constituents of the components of the battery and/or a surface diffusion rate.

An electrolyte wetting of 10 DEG might be set between a fiber network and the electrolyte. However, any other wetting angle between 0 and 180 is also possible to set. The surface diffusion rate can, as itself not be set. This problem was solved by constructing a layer around the specific surface (in this case copper) whereas the layer volume has a scalar diffusivity, which is significantly higher than the diffusivity in the electrolyte.

According to one embodiment of the invention the material parameter data and the simulation result data of the simulation model are provided to the AI model without any data cleaning and/or data filtering.

For instance, in order to investigate the effective diffusivity of the active material fiber network composite, first the morphology of the composite is constructed virtually, then a concentration gradient is applied and simulation is carried out. Subsequently, the system is able to calculate the effective diffusivity of the modelled sample based on Fick's law. Hereinafter, the AI model is also trained with the data of the same structure, i.e. all input data of the AI model comes from the simulation model. Furthermore, the AI model is on the aim of studying the microscopic structure of the material, therefore these data are all static data. (input data: diffusivity of each phase, concentration gradient; output data: concentration, flux, effective diffusivity). No fake, inaccurate, nor noise data is generated during the whole process.

Thus, data cleaning and/or filtering is not necessary since the material parameter data and simulation result data which is processed by the AI model originates from the simulation model and is not based on measured data which may comprise noise or wrong data. Therefore, time for cleaning and/or filtering data, which is the most time-consuming part of training an AI model, may be reduced. As a result, the AI model may learn a relation and correlation between the material parameter data (input) and simulation result data (output). The purpose of the AI model is to resemble the simulation model in order to substitute the simulation tool at some level. It is preferable if the AI model is not directly correlated to the real world.

Hence both material parameter data and simulation result data can be considered to be true data without any defects. However, the simulation result data is correlated at least partially to the real world with experiments in order to correlate the simulation result data with a physical meaning.

As mentioned above, although the material parameter data are from literature and experiment (real world), the output data is simulation result data. But the AI is constructed to learn the relation and correlation between input and output. In this case, there is no defects or faults in in and output data.

As for correlation, essentially, the material parameter data and geometric features are correlated with physical properties based on physical principles. This correlation is revealed by the simulation tool. With artificial intelligence the correlation is constructed by a specific ANN with a determined topology, number of layers and nodes.

For instance, with different amount of fibers and with different fiber diameters, a fiber network with various pore size distribution can be constructed. In order to investigate this characteristic, the fiber network is constructed virtually with input like e.g. fiber cross section geometry, fiber density, fiber length, fiber arrangement orientation, fiber curvature and so on. Then, on the basis of the granularity method, the pore size distribution is able to be calculated with simulation software. According to the simulation corresponding to the pore size distribution in the fiber network, a strong correlation between fiber density, fiber diameter, mean pore size and pore size standard deviation is observed. Through the simulation model, one is able to observe that the mean pore size is quasi-linearly proportional to the fiber diameter and inversely proportional to the fiber density. As for pore size deviation, with more fibers and smaller diameter, the deviation becomes smaller and the pore size distribution is more correlated to a Gauss distribution. The physics behind it is that with more fibers, the pore becomes smaller and the size is more homogeneously distributed.

However, with the simulation method, it is less efficient to quantitively investigate this behavior, since it is relevant to many parameters and it requires large computing power and consumes time to calculate. Thus, AI becomes a natural choice to investigate this connection. For instance, an ANN model can be used to investigate this behavior based on the input and output data of the simulation tool. Although in an ANN no physics principle is applied, however, the ANN is able to build a pure mathematical connection between the input and output parameters and reveal this behavior quantitively and efficiently, compared to simulation tool. More specifically, a deep feed forward neural network with 2 hidden layers, the first hidden layer contains 16 sigmoid nodes, the second hidden layer contains 4 linear nodes, can successfully predict the mean pore size and pore size deviation based on input fiber density and fiber diameter, with a mean standard error less than 5%, after 3000 iterations (epochs).

With similar methodology, other parameters with more complex physics behind it (e.g. conductivity, diffusivity) can be predicted with ANN.

According to one embodiment of the invention the material parameter data and the corresponding simulation result data are split into a material parameter/simulation result data set and a material parameter/simulation result test data set.

For example, the data set N=50 simulation runs with different parameters can be split into a set of training parameters for the AI with the number N₁=35, whereas the residual amount of simulations N₂=15 are used to check the data.

It is preferable if the training data set is selected randomly and homogenously, i.e. the training data is reaching every domain of the input data. It is particularly preferred if 70% of the material parameter data and simulation result data is used as training data and 30% of the material parameter and simulation result data as test data. If the material parameter and the corresponding simulation result data comprise a complete number of N samples (or N simulation runs), the N samples are divided into two different parts N1 and N2. N1 may comprise 70% of the data and N2 may comprise 30% of the data, while N1+N2=N. N1 is then used for training the AI model and N2 is used for testing the accuracy of the AI model. For instance, if a number of 50 simulations (=50 samples) is run by the simulation model, the simulation result data of 35 simulations (=35 samples) is used to train the AI model, whereas the simulation result data of the other 15 simulations (=15 samples) is used to test the AI's accuracy.

It is preferred if training of the AI model is terminated when the AI model is well-trained and preferably when an error of the AI model with respect to an error metric is smaller than a predefined error value. It is particularly preferred if the error of the AI model with respect to the test data is smaller than a predefined error value.

According to one embodiment of the invention an error metric for testing the accuracy of the AI model is selected from a member of the group of members consisting of a mean square error, a mean absolute error, a root mean squared error and the mean standard error. The error may further be an absolute or relative error. The absolute error may represent the error by an absolute value resulting from a difference between a prediction of the AI model and the simulation result data of the simulation model, whereas the relative error may represent the error by a relative deviation of the prediction of the AI model from the simulation result data. It is preferred if the error of the AI model comprises a relative error and in particular if the predefined error value is smaller than 10%, 5% or 3%. It is to be understood, that any other error metric may be used for testing the accuracy of the AI model.

For example, for mean pore size prediction, the error is calculated within every iterative step during AI preliminary training. The error is divided into 2 terms:
1. the mean absolute error (MAE) is calculated as the simulated mean pore size minus the AI predicted mean pore size, and then take the absolute value of it and calculate the mean value for all the absolute errors:

$$MAE = \frac{{\sum }_{i = 1}^{n} \vert {y}_{i} - {x}_{i} \vert}{n} = \frac{{\sum }_{i = 1}^{n} \vert {e}_{i} \vert}{n}$$

2. the mean standard error is the deviation of all the absolute errors.

During the training process of the AI model, in every step these 2 values are calculated, while the training goal is to minimize the mean absolute error and the mean standard error which are used as indicators to check if the training process is converging and under control. When the mean absolute error is smaller than a predefined error value (e.g. 5 μm), the training is stopped, and the AI model can be used as a prediction tool. After the first prediction, a relative error is calculated, and if this relative error is larger than a predefined value (e.g. 5%), the AI model need to be further trained with new simulation data.

According to one embodiment of the invention the AI model uses batch gradient descent, stochastic gradient descent or mini-batch gradient descent as an optimization algorithm. However, it is preferred if the AI model uses batch gradient descent to optimize the AI model.

As mentioned above, for pore size prediction, the available training data is from the simulation model and particularly from less than 100 simulation runs. Considering the amount of data we use batch gradient descent. Since the small amount of used data requires minimal computing power, a stochastic or mini batch is not necessary. Within the training process, 50 batches are set and the prediction accuracy is quite optimum (mean absolute error <5 μm).

In particular, the AI model uses an optimization algorithm selected from a group of members consisting of Momentum, Adam, Adagrad, Adadelta or RMSprop or a combination thereof. Preferably, the AI model employs a combination of Adam, RMSprop and a linear algorithm. However, any other optimization algorithm may be employed.

The nodes of the AI model may comprise any kind of activation function and preferably a rectified linear unit (RELU) and/or a linear function as activation function. However, other activation functions are possible. By way of example, the activation function may comprise a tan h function, a binary step function, a gaussian error linear unit (GELU), a softplus function, an exponential linear unit (ELU), a RELU, a linear function or a combination of the mentioned functions. Every node is able to comprise its own activation function which may be different from nodes in the same and/or other layers of the AI model. However, it is preferred if nodes of the same layer comprise the same activation function.

For instance, the AI model predicting the pore size comprises two hidden layers containing eight nodes and four nodes separately, the nodes in the first layer use the RMSprop algorithm and nodes in the second layer use linear algorithm as activation functions.

According to one embodiment of the invention the AI model comprises a machine learning model and preferably a deep learning model and even more preferably a Generative Adversarial Network, a Feedforward Neural Network (ANN), a Convolutional Neural Network (CNN), a Recurrent Neural Network (RNN) or a combination thereof.

For example, the AI model predicting the pore size is employed as a feedforward neural network to predict the pore size distribution. This can also be combined with a regression loop to resimulate structures in order to improve the error and estimation (regression loop from “data output AI” to “data input simulation”).

It is preferable if the AI model comprises a Feedforward Neural Network and a Recurrent Neural Network. For example, the Feedforward Neural Network predicts simulation result data related to microscopic geometric features, e.g. the pore size distribution or the contact area between active material and electrolyte, since it is more straightforward and linear. In contrast, the Convolutional Neural Network predicts simulation result data related to physical properties, e.g. conductivity or diffusivity, since the data is more complex, relevant to microscopic features of samples and the physical principle behind the corresponding data is highly nonlinear. However, both the ANN and CNN of the AI model may use at least partially the material parameter data as input. As for performance related features, a recurrent neural network (RNN) or a Long short-term memory neural network (LSTM) will be employed, since the charging and discharging data are nonlinear and time-related, RNN and LSTM are suitable for such input data.

More specifically, on the basis of the nature of the pore size distribution, the AI model predicting the pore size uses a deep feed forward ANN topology. Since the goal of AI is to predict geometrical features (pore size distribution), no time series data is involved, i.e. there is no correlation between 2 neighbouring data points, and no image data is included. Therefore, deep feed forward is preferred, compared to CNN (commonly used for image data) and RNN (data with time series). With deep feed forward topology, the AI is successfully trained and able to predict the mean pore size with a relative error less than 5%.

However, other topology may be employed when predicting other characteristics.

It is preferred if the ANN comprises two hidden layers, one input layer and one output layer, wherein the input layer is able to receive multidimensional input data, e.g. the material parameter data, and the output layer is able to output multidimensional output data, e.g. the simulation result data. Each hidden layer comprises a plurality of nodes. It is to be understood that the ANN may comprise an arbitrary number of hidden layers and/or nodes and that number of nodes per layer may vary. In order to obtain a good correlation with the structure of the fiber network, between 2 and 60.000 nodes were used in a layer, since the number of layers is determined by the amount of available data. More specifically, in case of the AI construction used for the pore size evaluation, 32 nodes were used for the first and 8 nodes were used for the second layer. However, it is preferred if the number of layers are in the range between 2-6000 nodes and even more preferred if they are between 4 and 600 nodes.

It is also preferred if the RNN comprises multiple hidden layers and one input and output layer. It is to be understood that the RNN may comprise one or more hidden layers and/or nodes and that the number of nodes per layer may vary.

When the training of the AI model is finished and the AI model is well-trained, the final accuracy of the AI model is evaluated based on extended data.

For the AI model predicting the pore size, after the training process, the material parameter data will automatically be extended. Subsequently the mean pore size is predicted by the AI model based on the extended material parameter data, while the simulation model is run correspondingly. Then a relative error is calculated for each extended material parameter data sample. This error matrix then reflects the accuracy of the AI.

According to one embodiment of the invention the extended material parameter data is generated by extrapolating the material parameter data. In particular, the extended material parameter data is set manually and/or by using an extrapolation strategy. Thus, flexibility of the method is ensured since the extended data and its property can be chosen according to preference. It is preferred if the extrapolation strategy is based on a fixed step extrapolation, a random extrapolation, an extrapolation function or any other kind of extrapolation strategy.

Here the extrapolation might be based on a physical theory (in case of the networks assembly on the percolation theory) or a random extrapolation according to power, exponential or linear relations. Additionally, the sparse matrix theory might be applied, which further reduces the number of required simulations.

It is preferable if the extended material parameter data is structured in the same shape as the material parameter data, i.e. the extended material parameter data comprises data on the same material properties as the material parameter data. It is further preferable if the extended material parameter data comprises one or more material parameter configurations which may be used to run the simulation model.

For example, the fiber diameter and the fiber density with respect to the pore size distribution and mean pore size of the resulting structure were simulated. Here, a parameter space of the fiber density from 0.075 to 2 v % and fiber diameters of 1 to 34 μm were generated and interpolated. All structures had the same shape and only the two parameters were varied. The parameter space afterwards was extrapolated to 80 μm fibers and 10 v % fiber density.

According to one embodiment of the invention evaluating a final accuracy of the AI model comprises: a step (A) inputting the extended material parameter data into the simulation model which outputs extended simulation result data; a step (B) inputting the extended material parameter data into the AI model which outputs predicted result data; a step (C) determining an uncertainty factor value χ based on a difference between the extended simulation result data and the predicted result data; and a step (D) finishing the training of the AI model, if the uncertainty factor value χ is smaller than a predefined uncertainty factor threshold value χ′, and repeating the previous steps (3) and (4), wherein the extended material parameter data is added to the material parameter data and the extended simulation result data is added to the simulation result data, otherwise.

It is preferred if both the simulation result data and predicted result data comprise a matrix, wherein each column of the matrix indicates a microscopic geometric feature and/or physical property and each column of the matrix indicates an index number of a simulation run, or vice versa. It is to be understood, that the extended simulation result data and material parameter data may be structured in any other kind of possible shape. It is also to be understood that by generating predicted result data based on the extended material parameter data, the AI model generates data beyond the simulated parameter space.

For instance, the AI model predicting the pore size is able to predict the fiber network with 5% fiber density and with 40 μm diameter, which is beyond the simulation parameter space. It is also the objective of this AI to explore the parameter space efficiently.

Hence, the difference between the extended simulation result data and the predicted result data comprises an error matrix. It is preferred if the uncertainty factor value χ comprises the highest value of the error matrix or an average of all values in the error matrix or any other kind of error evaluation metric.

According to one embodiment of the invention an accuracy of a prediction of the AI model is predicted by another integrated AI model. The integrated AI model may use the extended material parameter data as input and the corresponding error matrix as output for training in order to predict the expected error matrix. Based on the predicted error matrix of the integrated AI model the accuracy of the prediction of the AI model can be evaluated. As a result, the AI model is not only capable of predicting microscopic geometric features or physical properties but also of predicting the accuracy of the prediction itself.

When the final accuracy of the AI model is sufficiently high, i.e. the uncertainty factor value χ is smaller than a predefined uncertainty factor threshold value χ′, the AI model may be used independently and therefore replace the simulation model in order to determine the electrode's performance based on preliminary determined properties. Instead of simulating a structure and its material parameter data based on the simulation model, the AI model may be used to generate accurate predictions of the simulation result data based on the inputted material parameter data. As a result, the number of required simulations may be reduced. Moreover, the AI model may be used to test different material parameter configurations and determine the resulting performance of the electrode in order to optimize the material property of the electrode in an efficient way.

According to a further aspect of the invention a method for manufacturing a fiber network comprises the following steps:
1. inputting material parameter data, with said material parameter data relating to properties of constituents of components of the battery;
2. simulating one or more components and/or constituents of components of the battery using a simulation model which takes the material parameter data as input to generate simulation result data as output, with the simulation result data comprising at least one of the following data: data on microscopic geometric features of the component, data on a conductivity of the component, data on a current collector, data on a binder phase, data on a diffusivity of the electrolyte and data on a charging and discharging potential of the component;
3. fitting an AI model with material parameter data as input and the simulation result data as output;
4 evaluating a final accuracy of the AI model with respect to the simulation model using extended material parameter data;
5. using the AI model to output material properties of the constituents of the components of the battery;
6. manufacturing a fiber network based on the material properties of the constituents of the components of the battery, wherein the manufacturing of the fiber network comprises:
   step a) of providing a plurality of fibers and placing the fibers in a hot press or between a hot rolling calender and step b) of subjecting the plurality of fibers present in the hot press or the hot rolling calender to a predetermined pressure and temperature for a predetermined period of time to produce the network by sintering the plurality of fibers one to another forming points of contact between the fibers,
   wherein in step b) the pressure is at least 160 MPa and the temperature is between 20 to 95% of a melting temperature of the material of the fibers, wherein the melting temperature is determined by DSC measurement.

After a network of metal fibers has been manufactured by the above method, it is particularly preferred to cut the network into a shape suitable for a desired application. The cutting can be performed before or after a coating step and also if no coating step at all is intended. It facilitates the production of networks of metal fibers in desired shapes, if the cutting is performed after a network of metal fibers has been formed.

In this connection it should be noted that the advantages and features discussed in the foregoing in relation to the method for optimizing material properties of components of a battery may reliably be used in analogy to the method for manufacturing a fiber network

A further aspect of the invention relates to an electrode containing a fiber network, as described above, preferably produced according to the method described above. It is particularly preferred that the fiber network forming a part of the electrode has been separated, for example by cutting, from a network.

It is particularly preferable if the electrode contains the network as a current collector.

In the electrode according to the invention it is further preferable if the voids between the metal fibers in the network are at least partially filled with an active material, in particular with an active electrode material or a catalyst material which can be applied for homogeneous or heterogeneous catalysis (fuel cell, hydrolysis).

A further aspect of the invention relates to a battery comprising an electrode, such as described above and is a positive and/or a negative electrode.

The porous structure of the network of metal fibers provides for a comparatively large volume which can be occupied by active electrode material and is not present e.g. in a commonly used metal foil.

Accordingly, the amount of electrode active material can be significantly increased without compromising the capacity due to an increase in electrical resistance which is caused by the high amount of active electrode material. Moreover, by using a network of metal fibers as described above, the active material is distributed homogeneously throughout the current collector. Therefore, the electrons have to overcome only short distances between the active material and the current collector. As a result, charging times of the battery can be significantly reduced and the use of additives such as carbon black and binders can also be reduced so that more active material can be incorporated into the battery's electrode further improving the properties of the battery.

The flexibility and stability of a network of metal fibers allows for a durable electrode to be fabricated and as a consequence for a battery having an increased lifetime. In addition, the battery which makes use of the electrode according to the invention has improved battery charging kinetics due to the 3-dimensional nature of the metal network which penetrates the active electrode material. This enables short migration distances of electrons and charge carriers from its origin within the active material to a metal current collector from where it is distributed in the circuit.

It is preferred if the battery according to the invention is a secondary battery, more preferably a lithium ion battery. It is also preferable if the network is a network of copper metal fibers or copper-alloy fibers, e.g. Cu₉₆Si₄ or Cu₉₂Sn₈, or a network of aluminum metal fibers or aluminum-alloy fibers, e.g. Al₉₉Si₁. Copper-alloys and aluminum-alloys have better manufacturing conditions of the fibers with melt-spinning technique while they exhibit nearly the equal conductivity. Such techniques are explained by way of example in WO2020/229400 whose contents regarding the melt spinning technique is hereby included for the purpose of reference.

It is also preferable to provide a network of metal fibers, wherein the metal fibers are made of aluminum for a cathode of a secondary battery or made of copper for the anode of a secondary battery. Such a network can be infiltrated with a lithium active material or metallic lithium and used as the electrode. Also, in this case the distance between current collector and active material can be reduced which is beneficial for the performance of the battery.

Accordingly, it is in particular preferable if the battery according to the invention contains an electrode comprising a network of metal fibers of copper. It is also in particular preferable if the battery according to the invention contains an electrode comprising a network of metal fibers of aluminum. It is even more preferable if the battery according to the invention contains a first electrode comprising a network of metal fibers of copper and a second electrode comprising a network of metal fibers of aluminum.

The invention will now be described in further detail and by way of examples only with reference to the accompanying drawings and pictures as well as by various examples of the method of the invention. In the drawings there are shown:

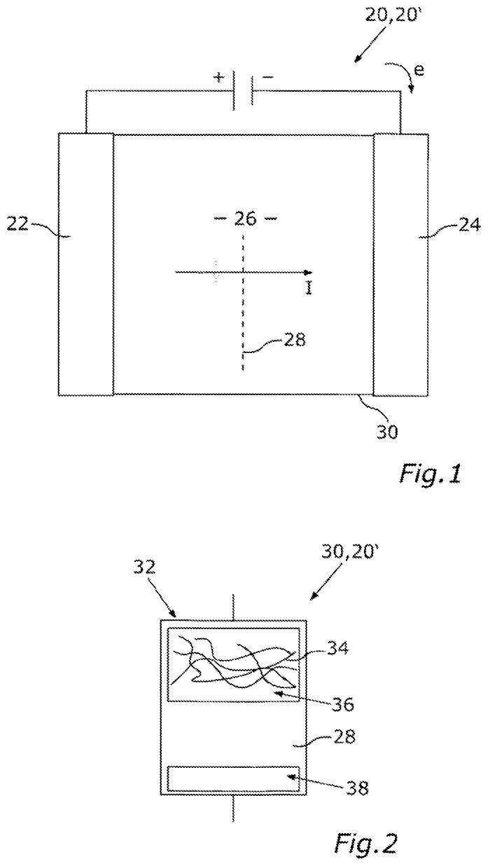

FIG. 1 a schematic view of components of a battery;

FIG. 2 a schematic view of a half cell;

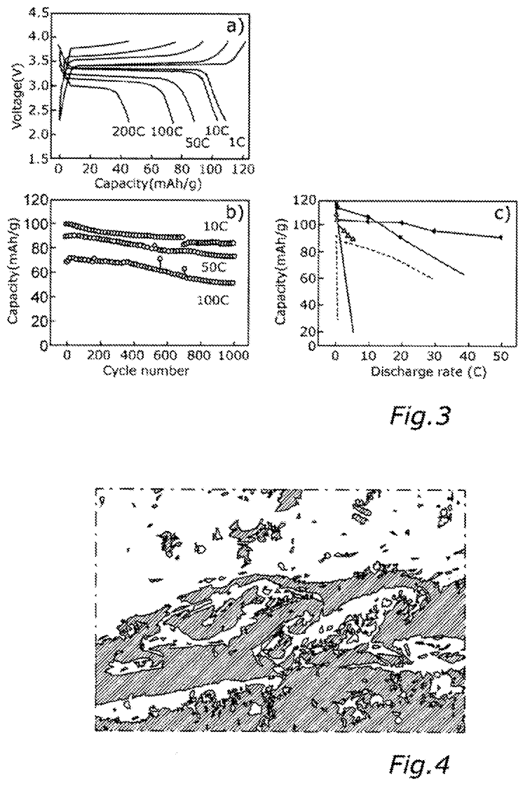

FIGS. 3a to 3c (a) typical galvanostatic charging-discharging profiles of prior art battery materials at different current rates, (b) typical cycling stabilities of prior art battery materials at various current rates, and (c) comparison of rate performances of various prior art battery materials;

FIG. 4 an SEM image of an electrode formed from a fiber network;

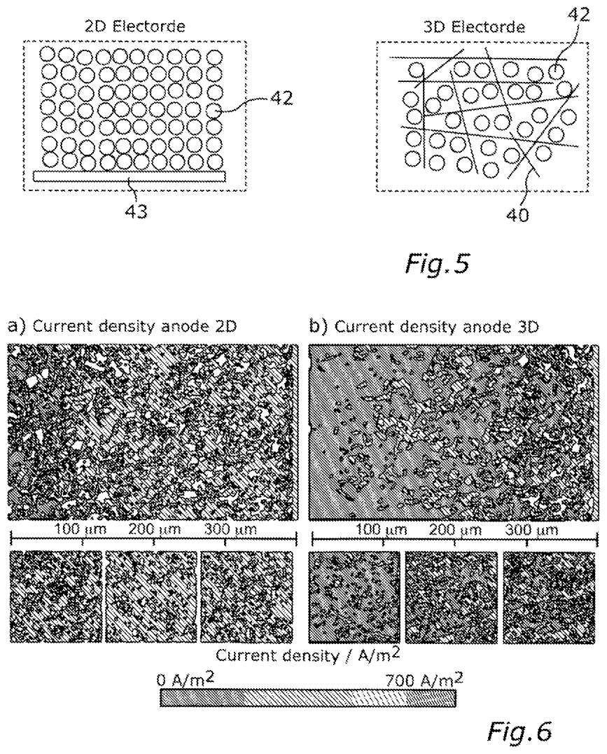

FIG. 5 a schematic view of a 2D and 3D electrode

FIG. 6 an illustration of the current density of a 2D and 3D anode

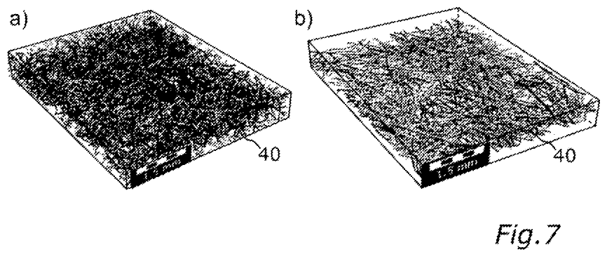

FIG. 7 a) simulated fiber network and b) scan of an experimental metal fiber network;

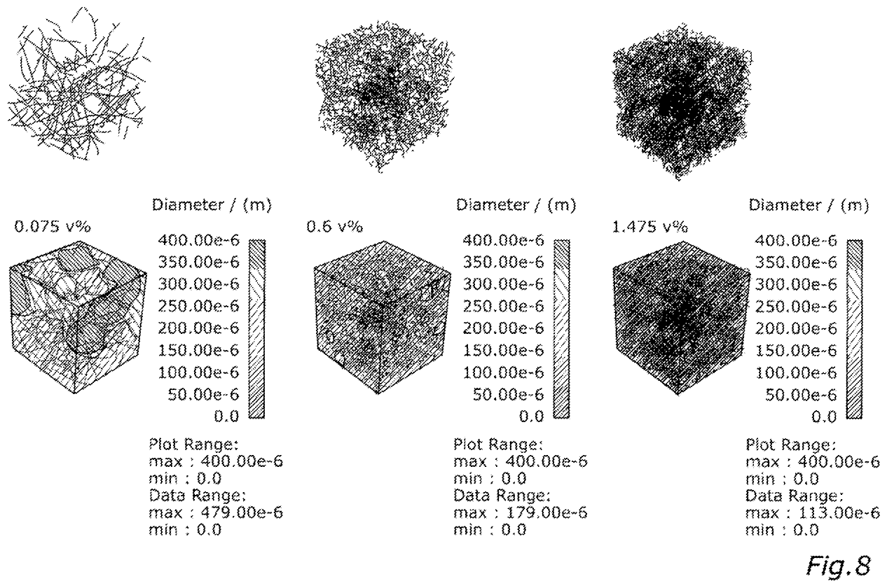

FIG. 8 simulated networks with respective porosity with a fiber diameter of 5 μm and a fiber volume fraction of a) 0.075 v %, b) 0.6 v % and c) 1.475 v %;

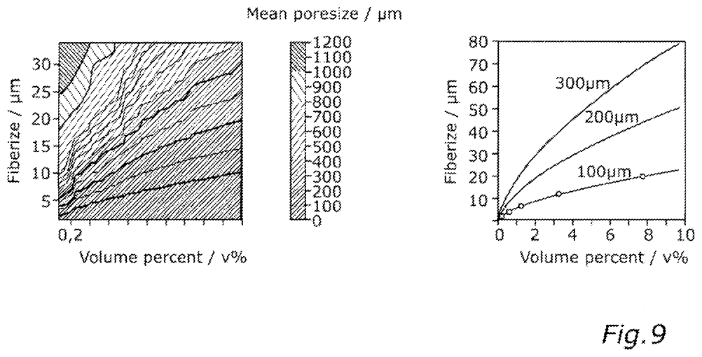

FIG. 9 a) a heat map correlating the respective fiber diameter (fiber size), the fiber density (volume percent) with the mean pore diameter (color coded) and b) the extrapolation of the heatmap to higher fiber diameters and large volume fractions

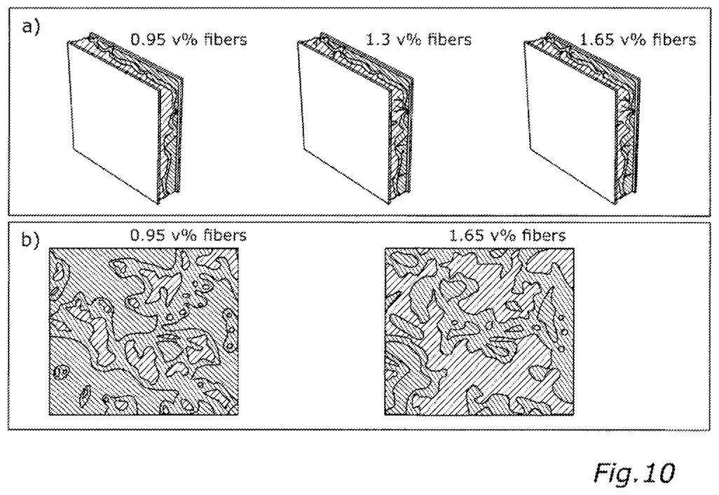

FIG. 10 effect of a network with different fiber densities on the potential field the a) 3D space and in the b) cross section;

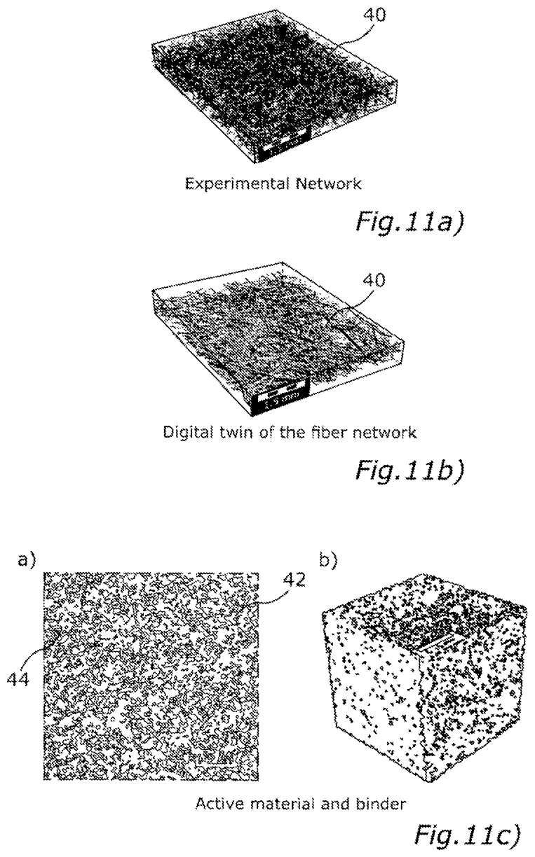

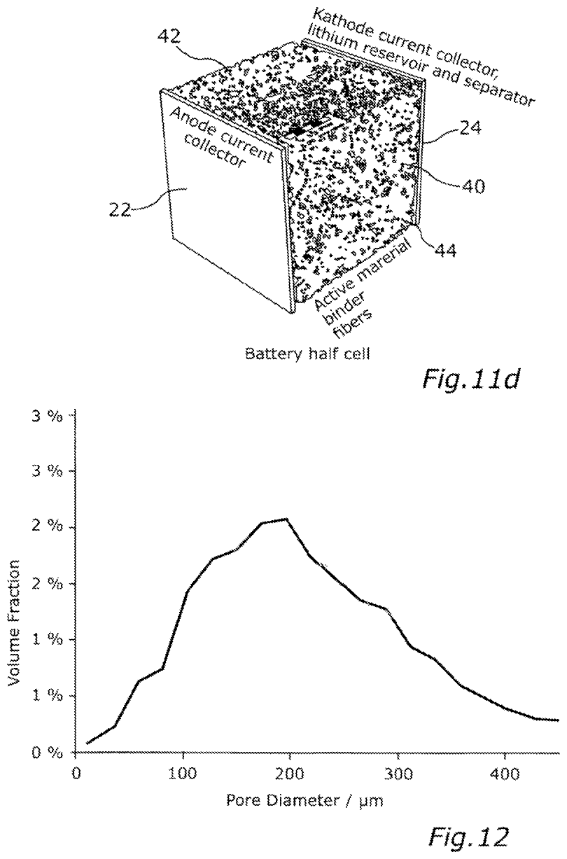

FIGS. 11a to 11d an illustration of the simulated components of the electrode

FIG. 12 a graph illustrating the relation between pore diameter and volume fraction of the pores

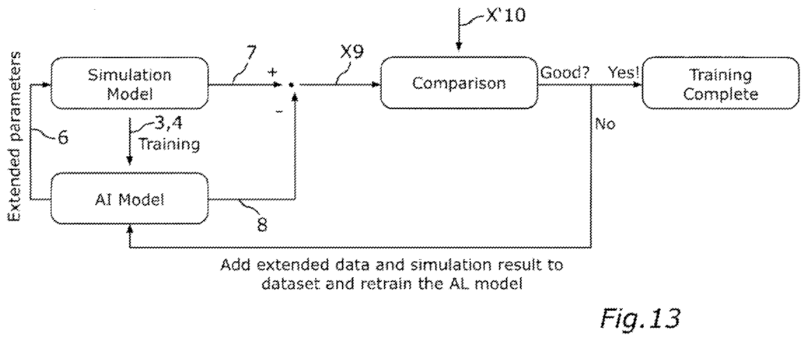

FIG. 13 workflow of the integrated simulation and AI model;

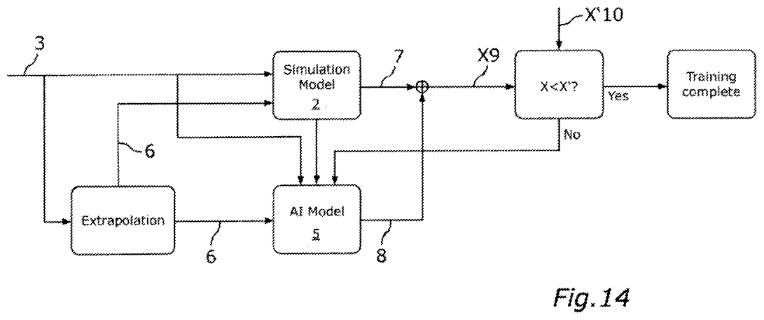

FIG. 14 a workflow of an integrated simulation and AI model;

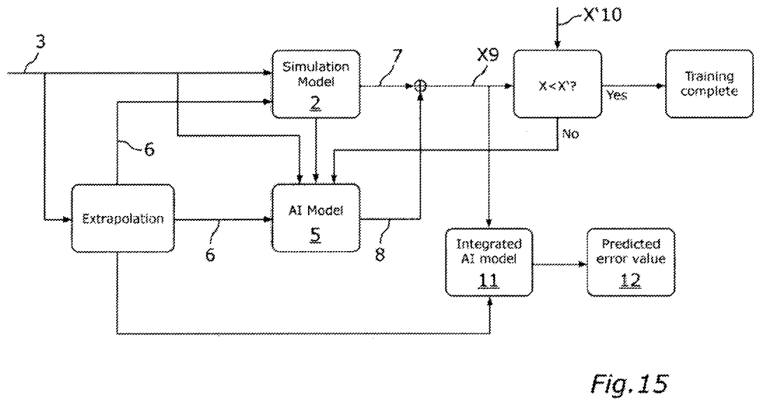

FIG. 15 a workflow of an integrated simulation and AI model with an additional integrated AI model;

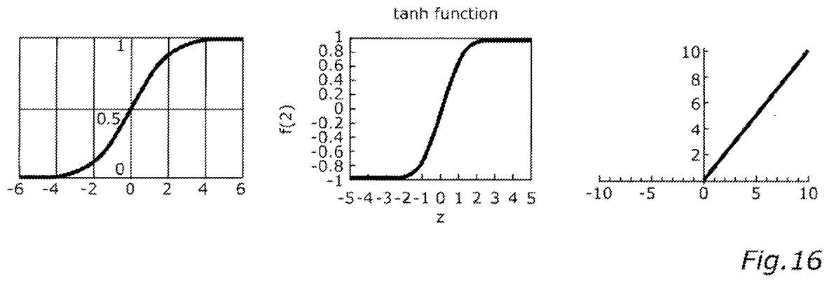

FIG. 16 activation functions of an AI model

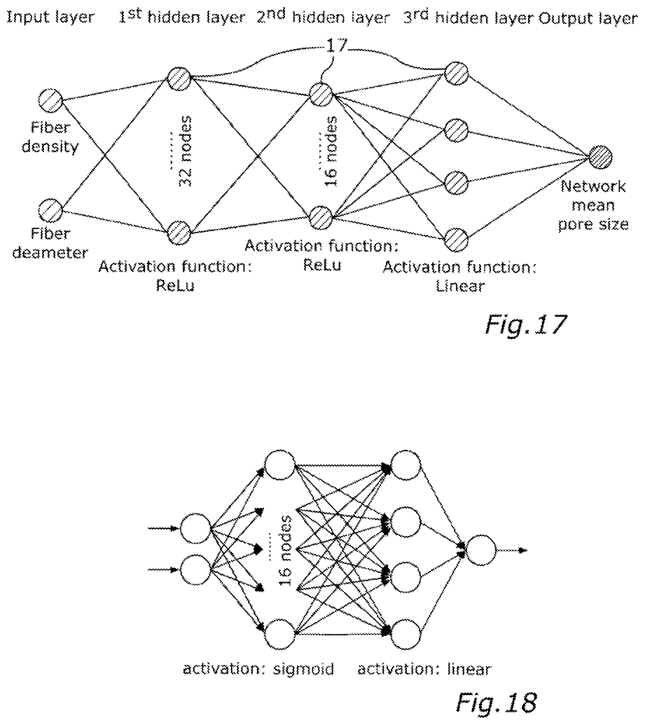

FIGS. 17 and 18 a topology of a DFF-ANN

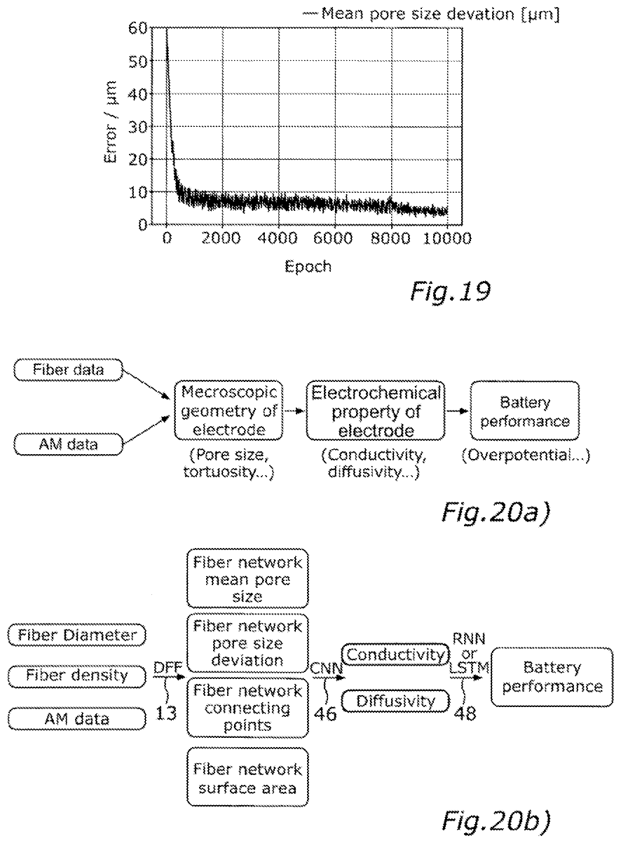

FIG. 19 an error graph of the mean pore size over 10000 epochs

FIG. 20a, 20b, 21 a workflow of an AI model;

FIG. 1 shows a schematic view of components 20′ of a battery 20. The components 20′ of the battery are an anode 22, a cathode 24, an electrolyte 26, a separator 28 and a battery 30 as known to the person skilled in the art.

FIG. 2 schematically shows a half-cell 30. The components 20′ of the half-cell including electrodes 34 and 36, separator 28 and an Li-foil 38. In this half-cell 30, the electrode 34 is assembled from a network of fibers 40.

Similarly, at least one of the anodes 22 and the cathodes 24 of the battery 20 shown in FIG. 1 can be formed from a network of fibers 40.

In order to quantify the quality of a battery it is known in the prior art to inspect Galvanostatic charging-discharging profiles of the intended anode, cathode, electrode in a respective half cell 30 such as the one shown in FIG. 2 for the respective battery material at different current rates. One also inspects the cycling stabilities of the components 20′ as shown in FIG. 3b. Thereafter the rate performance of the component 20′ of the battery 20 is compared to that of prior art components as indicated in FIG. 3c.

In this connection it should be noted that for the charge and discharge profiles shown at different current densities in FIG. 3a means the full capacity can be charged or discharged in one hour. The higher the charge number is e.g. 200 C the faster the battery can be charged and discharged, meaning that such a battery can deliver both high energy and high power density, i.e. current density can be increased to as high as 200 C. Hereby, the charging time would be reduced to 20 seconds.

The further quantification of a battery is to inspect how the cycling stability performs over time as indicated in FIG. 3b. The decay of the capacity over time is normal for a battery, however, the less steep the gradient is, the longer the lifetime of the respective battery is. On selecting an appropriate material for at least one of the anode 22, the cathode 24, the electrodes 34, 36 one also compares the different discharge rates in order to evaluate which of the battery materials is best suited for the desired application.

FIG. 4 shows an SEM image of a component that can be formed as an electrode 34, 36 of a half cell or as an anode 22 or cathode 24 of a battery 20. The component is formed by a network of metal fibers 40, in the present example the fibers consist of the copper alloy Cu₉₆Si₄.

In the network of metal fibers 40 a plurality of metal fibers 40 are fixed to one another. The metal fibers 40 have a length of 1.0 mm or more and preferably of less than 10 cm, a width of 100 μm or less and a thickness of 50 μm or less.

The fibers 40 may optionally have a circular or oval cross section area with a diameter less than 100 μm, preferably less than 10 μm. In case of an oval cross section, the mentioned diameter is the average diameter. For example, the oval cross section has the shape of an ellipse.

The network of fibers 40 is preferably flexible and can be deformed repeatedly without causing degradation of the network, i.e. without separating single metal fibers 40 out of the network of metal fibers 40 due to deformation.

The metal fibers 40 are fixed to one another, so that the metal fibers 40 contact each other, i.e. the point of contact is not movable relative to the metal fibers 40 as it is the case for example in a nonwoven agglomeration of entangled metal fibers such as a metal felt.

As a consequence, the network of metal fibers 40 is mechanically stable yet flexible. Mechanically stable in this context means that the network of metal fibers 40 is not a loose agglomeration of metal fibers 40, i.e. the network does not disintegrate into isolated metal fibers 40 as soon as a small force acts on the network. Accordingly, such a network of metal fibers 40 can be flexibly deformed without breaking.

It is possible that the network of metal fibers 40 recovers its form after deformation. However, if the network of metal fibers 40 is folded, it is also possible to reshape it permanently the metal fibers 40 are made of metal or a metal alloy or contain at least a metal. In the invention it is not particularly limited which metal is contained in the metal fibers 40 or from which metal the metal fibers 40 are made of.

Nevertheless, it is preferred that the metal fibers 40 of the plurality of metal fibers 40 in the network contain one of the elements selected from the group consisting of copper, silver, gold, nickel, palladium, platinum, cobalt, iron, chromium, vanadium, titanium, aluminum, silicon, lithium, combinations of the foregoing and alloys containing one or more of the foregoing.

It is further preferred that the metal fibers 40 of the plurality of metal fibers 40 in the network contain one of the elements selected from the group of members consisting of copper, silver, gold, nickel, palladium, platinum, iron, vanadium, aluminum, silicon, lithium, combinations of the foregoing and alloys containing one or more of the foregoing.

It is particularly preferred if the metal fibers 40 are made of copper or a copper alloy or of aluminum or an aluminum alloy or of a stainless steel alloy. Different types of metal fibers 40 can be combined with each other, so that the network can contain for example metal fibers 40 made of copper, one or more stainless steel alloys and/or aluminum. Networks of metal fibers 40, wherein the metal fibers are of copper, aluminum, cobalt, alloys containing copper, aluminum, silicon and/or cobalt are particularly preferred. Examples for aluminum and cobalt alloys are Al₉₉Si₁ and Co₆₆Fe₄Mo₂B₁₂Si₁₆. Examples for copper alloys are CuSi₁, CuSi₄ or CuSi₁₂.

It is preferable if the metal fibers 40 have a length of 1 mm or more, more preferable of 5 mm or more and even more preferable of 10 mm or more and even more preferably of 70 mm or more. With the length of the metal fibers 40 fulfilling the above length specification, mechanical stability of the network of metal fibers 40 is improved, since due to the increased length of the metal fibers 40, each metal fiber 40 can have several points of contact to other metal fibers 40 of the network where it is fixed to the respective other metal fibers 40 to form a mechanically strong and electrically conductive connection there between.

Therefore, when one connection between metal fibers 40 breaks, this does not compromise the overall structural integrity of the network or separate a metal fiber 40 from the network, since several other connections between the fibers are available, to hold the network together and provide the desired electrical conductivity. Preferably, fiber length should be in the range of 1 to 20 cm, more preferably in a range of 3 to 15 cm and even more preferably in a range of 4 to 8 cm, since then arranging the fibers by carding or solid or liquid dispersion is easily possible.

It is also preferable if the metal fibers 40 have a width of 80 μm or less, more preferable of 70 μm or less, even more preferable of 40 μm or less and most preferably of 15 μm or less. In addition, it is preferable that the metal fibers 40 have a thickness of 50 μm or less, more preferably of 30 μm or less, even more preferably of 10 μm or less and most preferably of 5 μm or less. Instead of a rectangular cross section of the fiber also a circular or elliptical cross section with dimensions as stated above is possible.

In the network of metal fibers 40 according to the invention it is also preferred that in the network a majority of the metal fibers 40 is in contact with one or more of the other metal fibers 40. This ensures that a high electrical conductivity is provided throughout the network. It is further preferred, that the network is an unordered network. Such an unordered network has a good electrical conductivity in every direction. Moreover, it is easier to produce an unordered network of metal fibers 40, compared to an order network of fibers 40. It is further preferred, that the fibers 40 in the network are combed in different directions to provide directionality of individual fibers 40 but still allowing conductivity through the network being equally in all possible directions. Accordingly, it is preferred that in the network some or all of the fibers 40 have an orientation, i.e. the lengths of the fibers 40 are not oriented randomly but have a predominant orientation in one or more spatial directions.

It is particularly preferable if the network of metal fibers 40 according to the invention the metal fibers 40 are fixed to one another at points of contact which are randomly distributed throughout the network of metal fibers 40. According to another inventive aspect, it is preferred that the points of contact are not randomly distributed but are provided e.g. in a peripheral region of the network of metal fibers 40 or that the metal fibers 40 are ordered so that also the point of contacts are ordered. It is further preferred that the points of contact at which the metal fibers 40 are fixed to one another are localized in specific areas and not provided evenly over the complete network of metal fibers 40. With the points of contact at which the metal fibers 40 are fixed to one another being present only in separated areas, it is possible that the fibers in between these areas have a high flexibility while at the same time the mechanical stability and good electrical conductivity is ensured.

It is further preferable if in the network of metal fibers 40 according to the invention the metal fibers 40 are fixed to one another at points of contact, where the metal fibers 40 are in contact with each other. Preferably, each of the metal fibers 40 has at least two points of contact with other metal fibers 40, more preferably at least three points of contact, even more preferably at least four points of contact.

It is particularly preferred if in the network of metal fibers 40 according to the invention the metal fibers 40 are fixed to one another at points of contact, wherein the points of contact are distributed throughout the network, so that throughout the 3-dimensional structure of the network of metal fibers 40 points of contact are present. Accordingly, the points of contact are not only provided in a certain area of the network of metal fibers 40 such as in the center or in the circumference of the network. It is possible that the points of contact are evenly distributed throughout the network. It is also possible that the density of points of contact has a gradient throughout the network, i.e. that the network has areas with a higher density of points of contact and areas with a lower density of points of contact. It is also possible to have ordered or random spatial distributions of points of contact.

The network according to the invention preferably has open pores between the metal fibers 40. The porosity of the network is preferably up to 85 vol %. It is also preferable that the porosity of the network is more than 90 vol %. It is even more preferable when the porosity is in the range of 85 vol % to 99.95 vol %. It is possible to incorporate active materials 42 into the open pores, such as active electrode 34, 36 materials or active catalyst materials. It is further preferable that in the network according to the invention at least some of the metal fibers 40 of the plurality of metal fibers 40 are at least partially coated. The coating can for example be an active material 42, such as an electrode 34, 36 active material which interacts with Li-ions in batteries or a catalytically active material 42 which coverts CO to CO2 or is active in hydrolysis. It is also possible to apply a coating onto the metal fibers 40 which improves the fixation of the metal fibers 40 to one another, and thereby increases the mechanical strength of the network.

By way of example, such active electrode materials 42 for batteries are: for the anode: Graphite, Silicon, Silicon-Carbide (SiC) and Tin-Oxide (SnO), Tin-Dioxide (SnO₂) and Lithium-Titanoxide (Li₄Ti₅O₁₂); and for the cathode: Lithium-NickelManganese-Cobalt-Oxide (LiNiₓMn_{y}C_{z}O₂ with x+y+z=1, NMC), Lithium-Nickel-Cobalt-Aluminium-Oxide (LiNiₓAl_{y}CO₂O₂ with x+y+z=1, NCA), Lithium-Cobalt-Oxide (LiCoO₂) and Lithium-Iron-Phosphate (LiFePO₄, LFP).

It is in particular preferable if the coating contains an active material 42 for an electrode of a secondary battery. Such a network of metal fibers 40 which is provided with a coating containing an active material 42 for the electrode of a secondary battery can be used to provide a flexible secondary battery which has an increased capacity. Moreover, it is possible to omit the use of a metal foil as current collector which not only improves the flexibility of the battery 20, but also reduces the battery's 20 weight.

In a further preferred embodiment of the invention, the network of metal fibers 40 has metal fibers which are coated with a coating comprising at least one catalytically active material 42, such as platinum, rhodium, palladium or other Nobel or catalytic metals. Such a network can be used as a catalyst. In particular, if the network has open pores and has the metal fibers 40 coated with a coating comprising at least one transition metal it is possible that a gaseous or liquid fluid can flow through the network, so that compounds contained in the fluid can come into contact with the coating provided on the metal fibers 40, so that a catalytic reaction can occur. Suitable metal alloys may also function as catalytic materials themselves such as nickel fibers.

Catalytically active materials 42 can be any materials capable of catalyzing a chemical reaction. It is particularly preferred that the catalyst material comprises one or more transition or noble metals.

It is further preferred if in the network according to the invention the plurality of metal fibers 40 form a network of interconnected pores.

It is further preferred if a coating which is provided on the plurality of metal fibers 40 is in electrical contact with the plurality of metal fibers 40. This is in particularly beneficial, if the network is used as an electrode material for fuel cells, in hydrolysis or batteries. A network containing the metal fibers 40 coated with the coating comprising an element suitable for catalyzing electrochemical reactions that occur at the electrodes 34, 36 of a fuel cell or a battery 20 is capable of transporting electrons to or from the reaction site. Accordingly, such a network can be used to improve the performance of a fuel cell or of a battery 20.

The thickness of the network of the invention is not particularly limited. However, it is preferred if the network has a thickness of 0.01 mm or more. It is more preferred that the thickness of the network is 0.1 mm or more, even more preferred 0.5 mm or more, even more preferred 0.7 mm or more and most preferred 1 mm or more. If the thickness of the network is less than 0.1 mm, there is a risk that the mechanical stability of the network is not sufficient. The upper limit for the thickness of the network is not particularly limited. However, depending on the application, the upper limit may be 3.0 mm or less, or 2.5 mm or less. For battery applications, the most preferred thickness of the network is in the range from 0.1 mm to 1 mm. A network with a thickness in this range is advantageous concerning the stacking and rolling of the active material coated network for producing batteries. It is also favorable for the diffusion of Li-ions in a reasonable time.

FIG. 5 shows a 2D and 3D electrode, wherein the 2D electrode comprises a copper foil layer 43 on the bottom and an active material 42 layer comprising active material 42 particles on top. In contrast, the 3D electrode comprises copper fibers 40, which are disposed between the active material 42 particles. With the 3D structure of the electrode more reaction surface for the reaction between the copper and the active material can be generated, hence a higher conductivity and diffusivity of the electrode can be obtained. Moreover, due to the fibers 40 which serve as a transportation system for the electrons and/or ions leaving the active material 42, the current density of the 3D anode can be reduced in comparison to the current density of the 2D anode as shown in FIG. 6. A reduced current density in the active material leads to a diminished current load which has positive effects on the aging of the battery cell.

On carrying out a method for optimizing material properties of components of a battery, one inputs material parameter data 3 into a simulation program. The material parameter data 3 relates to properties of constituents of the components of the battery 20. This can be for example, the material of the fibers 40, a size and length and shape of the fibers 40 etc.

The components to be simulated can be one of those described in the foregoing.

Thereafter a simulation is carried out taking account of the material parameter data 3 in order to simulate one or more components of the battery 20, such as a positive or negative electrode 34, 36, a current collector, a separator etc.

The simulation then outputs data relating to the simulated component such as data on microscopic geometric features of the component, data on a conductivity of the component, data on a current collector, data on a binder phase, data on a diffusivity of the electrolyte and data on a charging and discharging potential of the component.

An Artificial Intelligence model (AI model) 5 is subsequently trained on the basis of the material parameter data 3 as an input and the simulation result data 4 as an output.

To improve the efficiency of the method and of the results thereof, a final accuracy of the AI model 5 with respect to the simulation model 2 using extended material parameter data 6 is evaluated.

Consequently, the AI model 5 is used to output material properties of the constituents of the components of the battery.

It has hitherto been found that using a fiber network as an electrode material results in desirable batteries, hence the simulation can be based on the simulation of components having a fiber network as its constituently. Other possible constituents of the components of the battery are an active material 42 (AM), a binder 44, a conductive additive and an electrolyte etc.

The material parameter data 3 comprises data on the fiber network properties and/or data on the AM properties and/or data on the binder and/or data on the conductive additive and/or data on the electrolyte properties and is correlated with its structure.

The data on the fiber network properties are selected from a group of members consisting of a fiber density, a fiber length, a fiber curvature, a fiber cross section geometry, a fiber diameter, a fiber distribution orientation, a fiber conductivity or combinations of the foregoing.

The simulation model is based on a microstructure simulation of the constituents of the component of the battery 20. Alternatively, the microstructure simulation may be based on a Finite Volume Model (FVM) or a Finite Element Model (FEM). Such simulation models are typically based on physical approximations and mathematical principles.

On carrying out a microstructure simulation, the microstructure was simulated using the Program GeoDict von Math2Market. This simulated structure can and if possible should be correlated with an experimental structure. For example, a correlating microstructure of a real object can be obtained for example by using a Micro-CT scan and reconstruct the respective object.

On carrying out this method a network of metal fibers 40 was simulated and the resultant structure was compared to an experimentally obtained finite volume model (FVM) of a metal fiber network using the Micro-CT, as shown in FIG. 7.

FIG. 7a shows the simulated fiber network and FIG. 7b shows the scan of an experimental metal fiber network. The obtained structure was then simulated using GeoDict with the experimental fiber networks key parameter like fiber thickness and fiber diameter. Going beyond the reconstruction and simulation of the experimentally obtained fiber network scan, one started to simulate metal fiber networks composed of different amount of fibers 40 and subsequently determined their porosity, as shown in FIG. 8. The obtained key parameters for an experimental structure can be compared to the key parameters obtained from a simulated structure in order to correlate the simulated data with experimental data. For instance, if a CuSi4 network is fabricated and its fibers 40 have a diameter of 35 μm, the volume fraction which the fibers occupy in the network is 5 v % and the mean distance between the fibers 40 is at 195 μm one can directly correlate this experimental data with a simulated network based on the same key parameters.

FIG. 8 shows the simulated networks with the respective porosity with a fiber diameter of 5 μm and a fiber volume fraction of a) 0.075 v %, b) 0.6 v % and c) 1.475 v %.

Consequently, not only the fiber density in the metal fiber network was simulated, but also the fiber geometry, namely the fiber diameter was simulated. Along this line, one was not only able to find a correlation between fiber density and porosity, but also a cross-correlation between fiber density, fiber diameter and mean pore diameter. This was shown in FIG. 9 using the mean pore diameter of the metal fiber network as color coding.

FIG. 9a) shows a heat map correlating the respective fiber diameter (fiber size), the fiber density (volume percent) with the mean pore diameter (color coded). FIG. 9b) shows the extrapolation of the heatmap to higher fiber diameters and large volume fractions.

With this technique, one is able to show the correlations between multiple parameters and use mathematic fitting to predict the porosity at any given fiber diameter and fiber density, since the effect is of geometric nature. Our prediction can be verified using experimentally obtained parameters from a metal fiber network. The deviation of the predicted result from the experimentally obtained result is defined as a statistical error which is a measure for the uncertainty of the prediction.

In mathematical terms, a network is first simulated whilst varying one parameter (namely the fiber thickness) and obtained its property (mean pore diameter), leading to a parameter space which extends into two dimensions (n=2). However, taking the fiber density into account, another parameter is introduced, thus the parameter space in now in the form n+1 (n=3). In this form it is still possible using graphical means to determine a suitable parameter for the extrapolation. However, as indicated in the introduction the simulation of the electrodes 34, 36 will include additional parameters to improve the electrodes 34, 36 performance.

These networks are then subsequently filled with active material 42, binder 44 and electrolyte using generated structures based on statistical scans. For instance, the particle size and shape are based on prior FIB-SEM Scans of experimental graphite particles. Their statistical parameters (e.g. size distribution, shape) are used to simulate and generate the active material 42. In case of the exemplary simulation, the particles have a polyhedral shape, are isotropically distributed in the volume, have no overlap with surrounding material and possess the inherent material parameters (i.e. solid diffusivity of graphite concerning conductivity, ion diffusivity and maximum lithium concentration). Moreover, the additive may be filled into the active material 42 as flexible mass.

However, upon investigating the porous network as an electrode 34, 36 for lithium ion intercalation, the parameters which have a large influence on the electrode's performance are among others the conductivity of the AM 42, the current collector, the binder phase, the diffusivity of the electrolyte, the porosity of the electrode 34, 36 and many more. Exemplary, it is shown in FIG. 10 how the electrical conductivity of a different network structures is calculated.

FIG. 10 shows the effect of a network with different fiber densities on the potential field in a 3D space (a) and in a cross section (b). The color coding for the volume field is illustrated between 0 V and 0.11 V. It is apparent that a higher fiber density leads to a higher potential field and therefore to a higher conductivity.

However, the conductivity is only one of a multitude of parameters, which have an influence on the performance of the electrode 34, 36. Other relevant parameters may comprise a diffusivity, a charging and discharging potential or microscopic geometric features 14 of the electrode 34, 36. Since it is not possible to use graphical or mathematical means to correlate the electrodes' performance with the large number of parameters, an AI model 5 is trained to cross correlate the parameters in order to virtually design a material.

FIG. 11 illustrates single steps of the simulation of the electrode. In a first step an experimental fiber network as shown in FIG. 11a is obtained by manufacturing a fiber network with specific parameter values, e.g. a specific fiber density, fiber diameter, etc.

In a second step a digital twin of the fiber network shown in FIG. 11b is generated. For example, a correlating microstructure of the experimental fiber network of FIG. 11a can be obtained by using a Micro-CT scan and reconstruct the respective object. The digital twin is therefore based on a simulated structure which is correlated with the experimental structure of FIG. 11a.

Using common software, e.g. CT-AN from Bunker, GeoDict from Math2Market or any other comparable software, the Micro-CT scan of the microstructure may be reconstructed into a volume structure. On the basis of the volume structure or a multitude of them properties of the constituent of the components of the battery 22 may be obtained by mathematical evaluations, e.g. Euclidic Distance. The obtained structural values may be used and correlated with material parameter data 3 for the simulation model 2.

For instance, parameters of a copper-silicon-network (CuSi₄-network) with a fiber diameter of 35 μm, a volume fraction of 5 v % which is occupied by fibers in the network and a mean distance between the fibers of 195 μm, may be directly correlated with a corresponding simulated fiber network based on these parameters. In another example the obtained conductivity of the electrode 34, 36 can be correlated with 4-point conductivity measurements on an experimental electrode. Among others, similar experimental techniques can be applied for the respective properties, i.e. EIS/GITT or PGSE-NMR for diffusivity, charging-discharging tests on half or full cells for the charging/discharging profiles, contact angle measurements to obtain the wetting behavior.

Additionally, a digital twin of the active material 42 is generated as shown in FIG. 11c. Hereby a FIB SEM is used to obtain a model structure of the graphite particles and by mathematical means (bubble Point, Euclidian circle) the statistical size distribution and their geometry can be obtained. According to these statistical parameters, a finite volume model can then be reconstructed, which correlates with the experimental size and geometry of said particles. As such, the obtained model is a digital twin of the particles and structure.

In particular, the particles have a polyhedral shape, are isotropically distributed in the volume, have no overlap with surrounding material and possess the inherent material parameters, i.e. solid diffusivity of graphite concerning conductivity, ion diffusivity and maximum lithium concentration.

FIG. 11d shows a simulated structure of a battery half-cell comprising a simulated anode current collector, a simulated cathode current collector and active material (grey), binder (blue) and fibers (orange), wherein the simulated active material 42, binder 44 and fibers 40 are disposed between the two current collectors 22, 24.

The simulation of the fiber network and the simulation of the active material 42 and binder 44 are overlapped. This allows to run simulations of the fiber network and simulations of the active material 42 in parallel and therefore to minimize the required processing power. When overlapping both simulated structures the overlap volume fraction may be assigned as fiber material. Alternatively, the simulated fiber network may also be directly filled with active material 42 and the binder 44 phase may be simulated into the fiber network structure. The simulation of the active material 42 may comprise filling the binder 44 and/or the conductive additive into the active material 42 as flexible mass.

FIG. 12 is illustrating a geometric relationship between the pore diameter (X axis) and the corresponding volume fraction (Y axis). The AI model 5 is able to learn such geometric relationships and even correlations between microscopic geometric features 14 and physical properties 16. Moreover, the AI model may predict an electrode performance of the battery 2 based on the microscopic geometric features 14 and/or physical properties 16.

In order to be able to predict an electrodes' performance upon intercalation of lithium ions an artificial intelligence (AI) model 5 has been designed with the ability to find correlations in an n-dimensional parameter space and subsequently expand the parameter space.

The AI model 5 will be integrated with the simulation tool, and forms an integrated workflow as shown in FIG. 13. Specifically speaking, the multiscale material parameter data 3 as well as the corresponding simulation result data 4 from the simulation model 2 will be pre-processed and then a multiscale dataset is prepared to train the AI model 5, which is based on a compatible machine learning algorithm and in particular on a deep learning model. Since both the input and output data are entirely from the simulation model 2, data cleaning and filtering is not necessary, which saves a lot of time (data cleaning occupies circa 70% time of training an AI). Second, after the AI model 5 is well-trained, the model attempts to extend the multiscale material parameter data 3 space, send the extended material parameter data 6 back to the simulation model 2, run the simulation and get the resulting extended simulation result data 7, after comparing the resulting extended simulation result data 7 with the AI predicted result data 8, a uncertainty factor value 9 which is based on a difference between the extended simulation result data 7 and the predicted result data 8 can be determined. Hence, the simulation model 2 and the AI model 5 are successfully correlated. Thirdly, through comparison between the actual uncertainty factor value 9 and the predefined threshold uncertainty factor value 10, the AI model 5 will decide whether the model is good enough for prediction or will be retrained and calibrated according to the new dataset comprising the material parameter data 3, extended material parameter data 6, simulation result data 4 and extended simulation result data 7.

With this integrated workflow, the AI model 5 will be able to not only predict the performance of electrodes 34, 36 but also generate a meaningful pattern (or tendency) to show the factor of influence of each parameter, moreover with a small predefined uncertainty factor value 9, the AI model 5 may train itself iteratively and become more and more accurate and reliable. Hence with this model, an optimum parametric setting can be found which could maximum the electrode's performance while an accuracy of this setting is predicted. It is worthwhile to mention, that the AI model 5 will be combined with physical principles as well as logical correlation within the input parameters, thus the model is not a pure mathematical model (e.g. black box model), instead it has physical meanings. In conclusion, both simulation time and computing power is highly improved with this workflow.

Hence, the core of this workflow is to define a compatible machine learning algorithm which is able to fit our case. There are plenty of distinguished machine learning algorithms successfully be implemented to predict data and recognize pattern or data tendency in industrial and academic research. Meanwhile each of them owns their own edge as well as drawbacks. In the present case, the dataset features the following characteristics:
One or several quantities should be predicted (not category or cluster)
Multiscale input parameters (>3);
Each parameter describes a physical 16 or geometry property 14;
No time series data included;
No environmental or artificial impacts (no human error), all data come from simulation model;
AI model does not interact with neither reality nor environment;
The initial amount of data is relatively small (<50 samples);

Considering all these features an ANN (artificial neural network) supervised machine algorithm is used for data prediction due to the following reasons: first, ANNs are designed for multiscale input data processing (predict complex model). Second, it is more accurate than a regression algorithm dealing with physical property prediction. However, it is not suitable for dynamic calculation (dealing with time series data). Since no time series data is processed, an ANN is suitable. Third, the ANN is sensitive to the data error. Since no environmental impact of data nor human error data is processed, the ANN can perfectly handle the data. Fourth, since real output data is already available in the training dataset and the model itself does not interact with any environment, in other words the AI model does not need to make decisions, a supervised machine learning algorithm, namely an ANN, is chosen.

As no time series data is processed by the AI model 5, there is no need to add additional memory units or time delay unit for a transient property and therefore a deep feed forward (DFF) ANN 13 as shown in FIG. 13 is suitable, considering that the model has to predict geometric properties as well as physical properties (relatively complex), the ANN model will be constructed with two hidden layers between input and output data.

After training of the AI model 5 is completed and the AI model 5 is well-trained, a correlation analysis within all the input and output data can be run in order to extract weighted data from the AI model 5, which shows the factor of influence of each parameter to the electrode performance.

However, the AI model 5 itself is not able to correlate the material parameter data 3 from experiments and the simulation result data 4 directly. The AI model 5 is able to correlate the previously manufactured electrodes structures with simulated data, thus check the correlation between experimental and simulated result. However, the AI model 5 is not able to include the correlation between experimental and simulated property into its model and prediction.

Moreover, obviously there exists a deviation (uncertainty factor) compared to the rigorous simulation model 2, however the AI model 5 can be utilized to determine the performance of an electrode 34, 36 based on a preliminary determined property. Thus, the AI model 5 will be a time saving tool to recognize the electrode performance sensitivity to each parameter and can be utilized to find at least the zone where the optimum performance point may lay in.

FIG. 14 shows a workflow according to the principles of the invention illustrating the data streams of the various data. The method 1 comprises a simulation model 2 which simulates one or more components of a battery based on inputted material parameter data 3 and outputs simulation result data 4. The material parameter 3 and the simulation result data 4 are provided to an AI model 5 in order to train the AI model 5 with the material parameter data 3 as input and the simulation result data 4 as output/label.

The material parameter data 3 and corresponding simulation result data 4 are split into a training data set comprising for example 70% of the material parameter data 3 and simulation result data 4 and a test data set comprising 30% of the material parameter data 3 and the simulation result data 4. While the training data set is used for fitting the AI model 5, the test data set is used to determine an accuracy of the AI model 5.

The accuracy of the AI model 5 may be determined by an error value preferably based on an error metric which represents the error between the simulation result data 4 and the prediction of the AI model 5. During the fitting process, both mean squared error and mean absolute error are taken into consideration. The AI model 5 may be using a batch gradient descent algorithm and a combination of an Adam, RMSprop and a linear algorithm as optimization algorithms. When the error of the AI model 5 is smaller than a predefined error value which may be 10% or 5% or smaller, the preliminary training of the AI model 5 is finished.

In a next step the material parameter data 3 is extrapolated to generate extended material parameter data 6. The extended material parameter data 6 is processed both by the simulation model 2 and the AI model 5, wherein the simulation model 2 generates extended simulation result data 7 and the AI model 5 generates predicted result data 8, respectively. In a next step an uncertainty factor value χ 9 which is based on a difference between the extended simulation result data 7 and predicted result data 8 is calculated and compared to a predefined uncertainty factor threshold value χ′ 10 in order to evaluate the final accuracy of the AI model 5. The difference between the extended simulation result data 7 and predicted result data 8 may comprise an error matrix, wherein a column of the matrix indicates a microscopic geometric feature or physical property and a row of the matrix corresponds to an index number of a simulation run.

The uncertainty factor value χ 9 may be determined for example by selecting the highest value in the error matrix or by computing the average of all values in the error matrix. In order to evaluate the complete evaluation and prediction ability of the AI, the mean absolute error is used as the most intuitive error metrics. Since the individual cases (points) on which the error is too high have to be filtered out, therefore also the mean squared error is inspected. If the uncertainty factor value χ9 is smaller than the predefined uncertainty factor threshold value χ′ 10, the training of the AI model 5 is terminated and the AI model 5 may be used independently without the simulation model. If the uncertainty factor value χ 9 is higher than the predefined uncertainty factor threshold value χ′ 10 the extended simulation result data 7 and corresponding extended material parameter data 6 are added to the material parameter data 3 and simulation result data 4, respectively. The training of the AI model 5 is then repeated until the uncertainty factor value χ 9 is smaller than the predefined uncertainty factor threshold value χ′ 10.

FIG. 15 illustrates a workflow according to one embodiment of the invention which is similar to the workflow of FIG. 14. In addition to FIG. 14 another integrated AI model 11 predicts an error of the AI model 5 in order to be able to predict an accuracy of a prediction of the AI model 5. Therefore, the integrated AI model 11 uses the extended material parameter data 6 as input and the error matrix resulting from the difference between the extended simulation result data 7 and predicted result data 8 as output in order to predict the error matrix. The AI model may output the maximum value in the error matrix or an average of all values in the error matrix or any other kind of error based on the error matrix as a prediction error value 12 which may be used to determine an accuracy of the prediction of the AI model. The calculated error is based on the MSE.

FIG. 16 shows different activation functions which may be used for training the AI model 5 and in particular the deep learning model. Each node 17 of the AI model 5 may has its own activation function. FIG. 16a shows a sigmoid function, FIG. 16b a tan h function and FIG. 16c a rectified linear unit (RELU). There are other activation functions which can be used for training, e.g. a linear function, a binary step function, a gaussian error linear unit (GELU), a softplus function, an exponential linear unit (ELU) or a combination of the mentioned functions. Alternatively, or additionally each node within a layer may has the same activation function.

FIG. 17 shows a Deep Feedforward (DFF) ANN 13, which is able to predict the network mean pore size of the fiber network, comprising an input layer with the fiber density and fiber diameter as input, three hidden layers, wherein the first hidden layer comprises thirty-two nodes 17, the second hidden layer comprises sixteen nodes 17 and the third layer comprises four nodes 17, and an output layer with the network mean pore size as output. Each node of the first and second hidden layer comprises a RELU activation function, while the nodes of the third hidden layer comprise a linear activation function. The DFF 13 therefore is trained to predict the network mean pore size when the fiber density and the fiber diameter is inputted.

FIG. 18 illustrates another topology of a DFF-ANN 13, wherein the topology comprises an input layer, two hidden layers and an output layer. The first hidden layer comprises sixteen nodes 17 with a sigmoid activation function, while the second hidden layer comprises four nodes 17 with a linear activation function. The input layer comprises two input channels, e.g. for data on a fiber diameter and fiber density, whereas the output layer comprises one output channel, e.g. for data on a mean pore size of a fiber network. It is to be understood, that the number of hidden layers and the number of nodes 17 per hidden layer is adjustable. Same is true for the number of input and output channels of the AI model.

FIG. 19 shows the course of the AI model error over 10000 training iterations (epochs) for the ANN topology shown in FIG. 17, wherein the mean pore size of the fiber network was predicted. It is apparent that the error decreases exponentially and reaches a value of less than 7 μm after 10000 training epochs. Hence, the AI model 5 successfully learned the correlation between material parameter data 3 and simulation result data 4.

FIG. 20 a) shows a general workflow of an AI model 5, wherein the AI model 5 performs multiple steps. In a first step the AI model 5 takes the fiber network data and AM data as input and predicts the microscopic geometric features 14 of the electrode 34, 36, e.g. the pore size, the tortuosity, etc. In a second step the AI model 5 predicts electrochemical properties 16 of the electrode 34, 36, e.g. conductivity, diffusivity, etc., based on the previously predicted microscopic geometric features 14. In a third step the AI model 5 predicts the battery performance, e.g. overpotential, current density, etc., based on the previously predicted electrochemical properties 16.

FIG. 20 b) shows the workflow of the AI model 5 comprising three different network topologies: a DFF 13, a CNN 46 and a RNN 48. The DFF predicts geometric features of the fiber network, namely the fiber network mean pore size, pore size deviation, connecting points, surface area or other geometric features of the fiber network, based on the inputted fiber diameter, fiber density and AM data. The CNN 46 predicts the conductivity and diffusivity of the fiber network based on the predicted fiber network mean pore size, pore size deviation, connecting points and surface area. In a last step the RNN 48, e.g. a Long-Short-Term-Memory (LSTM) or Gated Recurrent Unit (GRU) architecture, predicts the battery performance based on the predicted conductivity and diffusivity of the fiber network. For example, the RNN 48 predicts the overpotential or current density or any other battery performance metric in order to evaluate the battery performance. The same workflow can be applied to the active material 42 and/or binder and/or carbon black phase. It is to be understood that any material parameter of the fiber network and/or the active material 42 and/or the binder 44 and/or carbon black phase can be used. It is also possible to train each of the network topologies independently or dependently, i.e. the parameters of a neural network topology are fixed or not fixed when training another network topology.

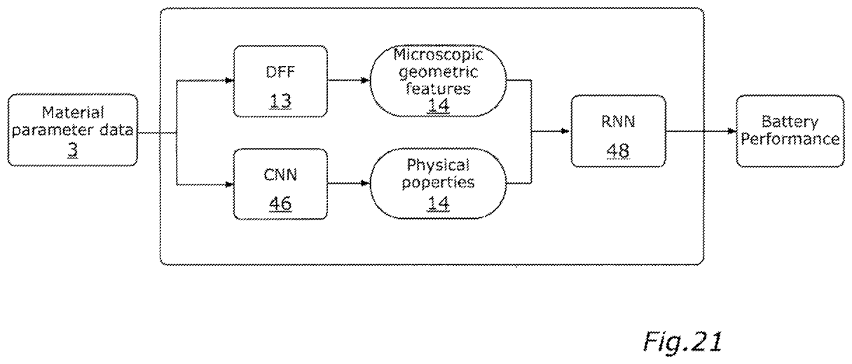

In FIG. 21 another embodiment of the AI model 5 is illustrated, wherein the AI model 5 processes material parameter data 3 as input and predicts the battery performance. According to FIG. 17 the AI model 5 comprises a DFF-ANN 13 which predicts microscopic geometric features 14 and a CNN 46 which predicts physical properties 16. The predicted data on the microscopic geometric features 14 and physical properties 16 is subsequently processed by a third model, namely the RNN 48, which outputs the battery performance in the form of the overpotential, current density, etc. Hence, the AI model predicted the microscopic geometric features 14 and the physical properties 16 in parallel which may reduce training time. It is to be understood, that a plurality of other AI topologies and combinations thereof may be used.

### LIST OF REFERENCE NUMERALS

1 method for optimizing material properties of components of a battery
2 simulation model
3 material parameter data
4 simulation result data
5 AI model
6 extended material parameter data
7 extended simulation result data
8 predicted result data
9 uncertainty factor value χ
10 uncertainty factor threshold value χ′
11 integrated AI model
12 predicted error value
13 DFF-ANN
14 microscopic geometric features
16 physical properties
17 node
20 battery
22 anode
24 cathode
26 electrolyte
28 separator
30 housing
32 half battery
34 electrode
36 electrode
38 Li foil
40 fibers
42 active material
43 copper foil layer
44 binder
46 CNN
48 RNN
e electron flow
l ion flow

1-48. (canceled)

49. A method for optimizing material properties of components of a battery, comprising the following steps:
(1) Inputting material parameter data, with said material parameter data relating to properties of constituents of the components of the battery,
(2) simulating one or more components and/or constituents of components of the battery using a simulation model which takes the material parameter data as input to generate simulation result data as output, with the simulation result data comprising at least one of the following data: data on microscopic geometric features of the component, data on a conductivity of the component, data on a current collector, data on a binder phase, data on a diffusivity of the electrolyte and data on a charging and discharging potential of the component;
(3) training an AI model with the material parameter data as input and the simulation result data as output;
(4) evaluating a final accuracy of the AI model with respect to the simulation model using extended material parameter data;
(5) using the AI model to output material properties of the constituents of the components of the battery.

50. The method of claim 49,
wherein the battery is an electrochemical energy storage device.

51. The method of claim 50,
wherein the electrochemical energy storage device is a multivalent-ion or monovalent-ion battery.

52. The method of claim 49,
wherein the components of the battery are selected from a group of members consisting of one or more electrodes, a current collector, a positive electrode, a negative electrode, a separator, an electrolyte, a binder, carbon black and combinations of the foregoing.

53. The method of claim 49,
wherein the constituents of the components of the battery are selected from a group of members consisting of a fiber network, an active material (AM), a binder, a conductive additive and an electrolyte and combinations of the foregoing.

54. The method of claim 53,
wherein the fiber network comprises a plurality of fibers and a material of the plurality of fibers comprises metal or carbon.

55. The method of claim 53,
wherein the active material is selected from a group of members consisting of graphite, silicon, silicon/carbon composite, silicon-dioxide/carbon composite, tin, tin-oxide, lithium metal of a lithium metal composite or Lithium-Nickel-Manganese-Cobalt-Oxide (NMC) in any kind of stoichiometry, Lithium Iron phosphate (LF(M,N,C)P), Spinel type manganese oxide (Mn2O4).

56. The method of claim 53,
wherein the binder is selected from a group of members consisting of polyvinylidene fluoride or styrene-butadiene copolymer, carboxymethylcellulose, polyvinylidene fluoride hexafluoropropylene, alginates and polyvinylalcohole.

57. The method of claim 53,
wherein the conductive additive is selected from a group of members consisting of carbon black, Super P in any kind of size, Carbon Nanotubes, graphene and metal nanowires.

58. The method of claim 53,
wherein the material parameter data comprises data on the fiber network properties and/or data on the AM properties and/or data on the electrolyte properties.

59. The method of claim 53,
wherein the data on the fiber network properties are selected from a group of members consisting of a fiber density, a fiber length, a fiber curvature, a fiber cross section geometry, a fiber diameter, a fiber distribution orientation, a fiber conductivity or combinations of the foregoing.

60. The method of claim 53,
wherein the data on the AM properties are selected from a group of members consisting of an AM fraction, AM particle size, AM particle shape, AM conductivity, AM diffusivity, AM equilibrium open circuit potential, AM reaction rate or combinations of the foregoing.

61. The method of claim 53,
wherein the data on the electrolyte properties are selected from a group of members consisting of an initial concentration, a transference number, an electrolyte diffusivity or combinations of the foregoing.

62. The method of claim 49,
wherein the simulation model is based on a microstructure simulation of the constituents of the component of the battery.

63. The method of claim 53,
wherein the simulation model comprises a simulation of the fiber network.

64. The method of claim 53,
wherein the simulation model comprises a simulation of the active material and/or the binder and/or the conductive additives.

65. The method of claim 49,
wherein the extended material parameter data is generated by extrapolating the material parameter data.

66. The method of claim 65,
wherein the extended material parameter data is set manually and/or by using an extrapolation strategy.

67. The method of claim 66,
wherein the extrapolation strategy is based on a fixed step extrapolation, a random extrapolation or an extrapolation function.

68. The method of any of claim 49,
wherein step (4) comprises:
(4.1.) inputting the extended material parameter data into the simulation model which outputs extended simulation result data;
(4.2.) inputting the extended material parameter data into the pretrained AI model which outputs predicted result data;
(4.3.) determining an uncertainty factor value based on a difference between the extended simulation result data and the predicted result data; and
(4.4.) finishing the training of the AI model, if the uncertainty factor value is smaller than a predefined uncertainty factor threshold value, and repeating the previous steps (3) to (4), wherein the extended material parameter data is added to the material parameter data and the extended simulation result data is added to the simulation result data, otherwise.

69. The method of claim 68,
wherein the difference between the extended simulation result data and the predicted result data comprises an error matrix.

70. The method of claim 69,
wherein the uncertainty factor value comprises the highest value in the error matrix or an average of all values in the error matrix.

71. The method of claim 49,
wherein the accuracy of the AI model is predicted by another integrated AI model.

72. A method for manufacturing a fiber network, comprising:
(1) inputting material parameter data, with said material parameter data relating to properties of constituents of components of the battery,
(2) simulating one or more components and/or constituents of the components of the battery using a simulation model which uses the material parameter data to generate simulation result data, with the simulation result data comprising at least one of the following data: data on a porosity of the component, data on a conductivity of the component, data on a current collector, data on a binder phase and data on a diffusivity of the electrolyte;
(3) fitting an AI model to the material parameter data and to the simulation result data;
(4) evaluating a final accuracy of the AI model with respect to the simulation model using extended material parameter data;
(5) using the AI model to output the material properties of the constituents of the components of the battery;
(6) manufacturing a fiber network based on the determined material properties of the constituents of the components of the battery, wherein the manufacturing of the fiber network comprises:
step a) providing a plurality of fibers and placing the fibers in a hot press and
step b) subjecting the plurality of fibers present in the hot press to a predetermined pressure and temperature for a predetermined period of time to produce the network by sintering the plurality of fibers one to another forming points of contact between the fibers,
wherein in step b) the pressure is at least 160 MPa and the temperature is between 20 to 95% of a melting temperature of the material of the fibers, wherein the melting temperature is determined by DSC measurement.

73. An electrode containing a fiber network according to claim 72.

74. A battery comprising an electrode according to claim 73.
